(19) United States
(12) Patent Application Publication
(10) Pub. No.: US 2018/0123085 A1
(43) Pub. Date: May 3, 2018

(54) FUNCTIONAL FILM

(71) Applicant: FUJIFILM Corporation, Tokyo (JP)

(72) Inventors: Kenichi KAKISHITA, Kanagawa (JP); Satoshi KUNIYASU, Kanagawa (JP); Kyohisa UCHIUMI, Kanagawa (JP); Makoto KAMO, Kanagawa (JP); Tatsuya OBA, Kanagawa (JP)

(73) Assignee: FUJIFILM Corporation, Tokyo (JP)

(21) Appl. No.: 15/848,997

(22) Filed: Dec. 20, 2017

Related U.S. Application Data
(63) Continuation of application No. PCT/JP2016/069078, filed on Jun. 28, 2016.

(30) Foreign Application Priority Data
Jun. 29, 2015 (JP) 2015-130445
Aug. 12, 2015 (JP) 2015-159622

(51) Int. Cl. H01L 51/52; H01L 51/50; G02F 1/017; B82Y 20/00

(52) U.S. Cl. CPC H01L 51/5253; H01L 51/502; H01L 33/50; B82Y 20/00; G02F 1/01708

(57) ABSTRACT

The present invention provides a functional film having an optical functional layer that exhibits an optical function and is capable of suppressing deterioration of the optical functional layer, and a method thereof. The functional film includes an optical functional layer, a resin layer which surrounds end surfaces of the optical functional layer, and gas barrier supports between which the optical functional layer and the resin layer are sandwiched, in which an oxygen permeability of the resin layer is 10 cc/(m²·day·atm) or less, and a difference between a thickness of the optical functional layer and the resin layer is within 30%; and a production method including forming a frame-shaped resin layer on a surface of a first gas barrier support, filling the inside of the frame with a polymerizable composition which becomes an optical functional layer, laminating a second gas barrier support on the resin layer, and curing the polymerizable composition.

### CROSS-REFERENCE TO RELATED APPLICATIONS

This application is a Continuation of PCT International Application No. PCT/JP2016/069078 tiled on Jun. 28, 2016, which claims priority under 35 U.S.C. § 119(a) to Japanese Patent Application No. 2015-130445 filed on Jun. 29, 2015 and Japanese Patent Application No. 2015-159622 filed on Aug. 12, 2015. Each of the above applications is hereby expressly incorporated by reference, in its entirety, into the present application.

### BACKGROUND OF THE INVENTION

### 1. Field of the Invention

The present invention relates to a functional film. In particular, the present invention relates to a functional film including a material whose performance is easily deteriorated by oxygen or the like.

### 2. Description of the Related Art

A functional film having an optical function is produced by forming a coating film by applying a polymerizable composition including a material having functionality such as optical properties or the like to a flexible support.

However, among materials having functionality, there is a material whose functionality is deteriorated by oxygen and this material causes a problem in the production of a functional film. As the material whose functionality is deteriorated by oxygen, for example, there is a quantum dot (QD, also referred to as quantum point) used as a light emitting material for a flat panel display such as a liquid crystal display device (hereinafter, also referred to as LCD).

For example, recently, in the flat panel display market, improvement in color reproducibility has progressed as improvement of LCD performance, and a quantum dot has attracted attention as a light emission material.

For example, quantum dots are used for a quantum dot layer (quantum dot-containing layer) formed by dispersing the quantum dots in a binder which becomes a matrix. In a case where exciting light is incident on a quantum dot layer, the quantum dot is excited and emits fluorescent light. Here, by using the quantum dots having different light emission properties, white light can be realized by emitting light having a narrow half-width of red light, green light, and blue light each. Since the fluorescent light by the quantum dots has a narrow half-width, wavelengths can be properly selected to thereby allow the white light to be designed so that the white light is high in brightness and excellent in color reproducibility.

Due to the progress of such a three-wavelength light source technique using quantum dots, the color reproduction range has been widened from 72% to 100% in terms of current television (TV) standards (Full High Definition (FHD)) and National Television System Committee (NTSC) ratio.

However, the quantum yield of quantum dots is deteriorated by oxygen and water vapor. As a countermeasure against this problem, sealing quantum dots with a member having gas barrier properties is performed.

For example, US2015/0047765A discloses that in order to protect quantum dots from oxygen and water vapor, a hydrophobic domain including quantum dots is formed in a hydrophilic domain in a quantum dot layer (quantum dot film).

Specifically, in the quantum dot layer disclosed in US2015/0047765A, as conceptually shown in FIG. 1B, quantum dots are incorporated in a domain D1 formed of a hydrophobic resin having good quantum dot (small white circle) dispersion stability and the hydrophobic domain D1 is surrounded by a domain D2 formed of a hydrophilic resin having low oxygen permeability. Then, the function of the quantum dots is not impaired and the deterioration of the quantum dots by oxygen is prevented.

### SUMMARY OF THE INVENTION

However, in the quantum dot layer disclosed in US2015/0047765A, since the resins forming the two domains are phase-separated, it is not always easy to form a stable dispersion. That is, the dispersion stability of the domain D1 including quantum dots in the domain D2 is not sufficient and as a result, a state in which the domains D1 are aggregated in the domain D2 as conceptually shown in FIG. 1C is attained without attaining an ideal dispersion state (sea-island structure) as shown in FIG. 1B. Therefore, it is found that it is difficult to stably form a film in which the inherent quantum efficiency of quantum dots is maintained in this structure.

In addition, in order to form the domain D2 in which the hydrophilic resin having low oxygen permeability becomes a continuous phase, it is required to increase the relative amount of the resin and a problem of an increase in the film thickness of the quantum dot layer arises. Further, since the quantum yield of light emission of the quantum dots depends on a difference in refractive index between the reins forming the two domains, the degree of freedom of resin selection is not high in this structure.

These problems are not limited to the quantum dots and are common in the production of a functional film using a polymerizable composition including a material whose performance is deteriorated by oxygen.

The present invention is made in consideration of the above circumstances and relates to a functional film including a functional material whose performance is deteriorated by oxygen, water vapor, and the like. An object thereof is to provide a functional film without impairing the performance of a functional material and without causing deterioration in performance over time, and a method of producing the functional film.

In order to achieve the object, according to the present invention, there is provided a functional film comprising: an optical functional layer; a resin layer that surrounds end surfaces of the optical functional layer; and gas barrier supports between which the optical functional layer and the resin layer are sandwiched,

in which an oxygen permeability of the resin layer is 10 cc/(m²·day·atm) or less, and a difference between a thickness of the optical functional layer and a thickness of the resin layer is within 30%.

According to the functional film of the present invention, the optical functional layer is surrounded by the gas barrier supports and the frame-shaped resin layer. Accordingly, since the intrusion of oxygen into the optical functional layer or the like can be prevented, even in a case where the optical functional layer includes a material whose performance is deteriorated by oxygen, it is possible to prevent deterioration in the performance of the functional film.

Further, although described later, as conceptually shown in FIG. 1A, by separately providing a resin layer 14 on an end surface of an optical functional layer 12 into which the oxygen intrudes instead of the inside of the optical functional layer 12, it is possible to keep the dispersion stability (dissolution stability) of a functional material such as a quantum dot excellent and to prevent deterioration in the performance of the functional film. In FIG. 1A, a gas barrier support 16 on an upper surface side is not illustrated.

In the functional film of the present invention, it is preferable that an oxygen permeability of the gas barrier support is 0.1 cc/(m²·day·atm) or less. According to the aspect, it is possible to prevent deterioration by oxygen for a longer period of time.

It is preferable that the optical functional layer includes a cured product of a polymerizable compound as a binder, and a binder infiltrated layer formed by infiltration of the binder into the resin layer has a width of 0.01 to 10 μm in a plane direction of the optical functional layer. According to the aspect, it is possible to prevent deterioration by oxygen for a longer period of time by improving the adhesiveness between the resin layer and the optical functional layer.

It is preferable that the functional film further includes an inorganic layer that covers at least a part of an outer end surface of the resin layer.

In addition, it is preferable that the inorganic layer is formed of metal.

Further, it is preferable that a plurality of the inorganic layers are provided.

According to these aspects, it is possible to prevent deterioration by oxygen for a longer period of time,

According to the present invention, there is provided a method for producing a functional film comprising: a resin layer forming step of forming a resin layer having an oxygen permeability of 10 cc/(m²·day·atm) or less on a surface of a first gas barrier support in a frame shape; a filling step of filling an inside of a frame formed by the resin layer with a polymerizable composition, which becomes an optical functional layer, such that a difference between a thickness of the optical functional layer and a thickness of the resin layer is within 30%; a lamination step of laminating a second gas barrier support on a side of the resin layer opposite to the first gas barrier support; and a curing step of curing the polymerizable composition.

According to the method for producing a functional film of the present invention, it is possible to laminate the resin layer and the optical functional layer between the barrier films with an inorganic layer without a void.

In the method for producing a functional film of the present invention, it is preferable that the filling step is performed after the resin layer forming step is performed, the lamination step is performed after the filling step is performed, and the curing step is performed after at least one of the filling step or the lamination step.

In addition, it is preferable that the resin layer forming step is performed such that a part of the frame formed by the resin layer is opened, after the lamination step is performed, the filling step is performed such that the inside of the frame formed by the resin layer is filled with the polymerizable composition from an opening portion, after the filling step is performed, the curing step is performed, and after the filling step or the curing step is performed, a sealing step of sealing the opening of the frame formed by the resin layer is farther preformed.

According to the aspect, it is possible to more suitably laminate the resin layer and the optical functional layer between the barrier films with an inorganic layer without a void.

It is preferable that the method further includes an end surface sealing step of covering at least a part of an outer end surface of the resin layer with an inorganic layer.

According to the aspect, it is possible to produce a functional film capable of preventing deterioration by oxygen for a long period of time.

According to the functional film of the present invention, in the functional film having the optical functional layer, it is possible to suppress deterioration in the optical functional layer by oxygen or the like. In addition, according to the method for producing a functional film of the present invention, it is possible to suitably produce the functional film of the present invention by laminating the resin layer and the optical functional layer between the gas barrier supports without a void.

### BRIEF DESCRIPTION OF THE DRAWINGS

FIG. 1A is a plan view conceptually showing an optical functional layer of a functional film according to the present invention.

FIG. 1B is a plan view conceptually showing a quantum dot layer of a functional film of the related art.

FIG. 1C is a plan view conceptually showing the quantum dot layer of the functional film of the related art.

FIG. 2 is a view conceptually showing an example of the functional film according to the present invention.

FIG. 3 is a view conceptually showing another example of the functional film according to the present invention.

FIG. 4 is a view for illustrating an example of a method for producing a functional film according to the present invention,

FIG. 5A is a conceptual view for illustrating an example of the method for producing the functional film according to the present invention.

FIG. 5B is a conceptual view for illustrating the example of the method for producing the functional film according to the present invention.

FIG. 5C is a conceptual view for illustrating the example of the method for producing the functional film according to the present invention.

FIG. 5D is a conceptual view for illustrating the example of the method for producing the functional film according to the present invention.

FIG. 5E is a conceptual view for illustrating the example of the method for producing the functional film according to the present invention.

FIG. 6A is a conceptual view for illustrating another example of the method for producing the functional film according to the present invention.

FIG. 6B is a conceptual view for illustrating the other example of the method for producing the functional film according to the present invention.

FIG. 6C is a conceptual view for illustrating the other example of the method for producing the functional film according to the present invention.

FIG. 7 is a conceptual view for illustrating another example of the functional film according to the present invention.

FIG. 8A is a conceptual view for illustrating an example of a method for producing the functional film shown in FIG. 7.

FIG. 8B is a conceptual view for illustrating the example of the method for producing the functional film shown in FIG. 7.

FIG. 8C is a conceptual view for illustrating the example of the method for producing the functional film shown in FIG. 7.

FIG. 8D is a conceptual view for illustrating the example of the method for producing the functional film shown in FIG. 7.

FIG. 9A is a conceptual view for illustrating another example of the method for producing the functional film shown in FIG. 7.

FIG. 9B is a conceptual view for illustrating the other example of the method for producing the functional film shown in FIG. 7.

FIG. 9C is a conceptual view for illustrating the other example of the method for producing the functional film shown in FIG. 7.

### DESCRIPTION OF THE PREFERRED EMBODIMENTS

Hereinafter, a functional film and a method for producing a functional film according to the present invention will be described with reference to the accompanying drawings.

The present invention is a technique concerning a functional film having an optical functional layer including a material which is deteriorated in performance by oxygen and water vapor and exhibits an optical function, and a method for producing the functional film.

In the following description, a functional film having an optical functional layer as a wavelength conversion layer including quantum dots as a material whose performance is deteriorated by oxygen will be described as an example. However, the present invention is not limited to the quantum clots and can be applied to all functional films having an optical functional layer including a material which is deteriorated in performance by oxygen and exhibits an optical function.

In the specification, any numerical range expressed herein using “to” refers to a range including the numerical values before and after the “to”, as the upper limit and the lower limit, respectively.

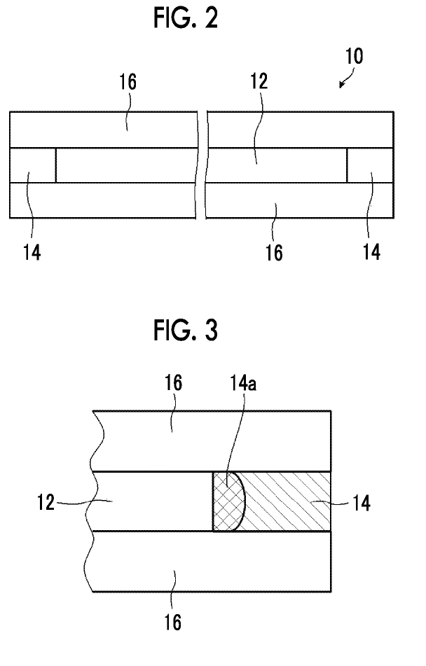

In FIG. 2, an example of a functional film of the present invention is conceptually shown.

A functional film 10 shown in FIG. 2 includes an optical functional layer 12, a resin layer 14, and gas barrier supports 16. Specifically, the resin layer 14 is provided so as to surround the end surfaces of the optical functional layer 12 and the optical functional layer 12 and the resin layer 14 which surrounds the end surfaces of the optical functional layer 12 are sandwiched between the gas barrier supports 16 so that the primary surface (the largest surface) of the optical functional layer 12 is interposed therebetween.

The optical functional layer 12 is a layer exhibiting an optical function such as wavelength conversion or fluorescent light emission and is formed by, for example, dispersing or dissolving a substance exhibiting an optical function, such as a quantum dot in a hinder which becomes a matrix. The resin layer 14 covers the end surfaces of the optical functional layer 12 and blocks the intrusion of oxygen and water vapor from the end surface. The gas barrier support 16 covers both primary surfaces of the optical functional layer 12 and blocks the intrusion of oxygen and water vapor from these surfaces.

By arranging the optical functional layer 12 in a region separated from the outside by the resin layer 14 and the gas barrier supports 16, the optical functional layer 12 is isolated from oxygen or water vapor which is one of substances causing deterioration thereof and thus can continuously exhibit good performance for a long period of time. That is, by arranging the optical functional layer 12 in the region separated from the outside by the resin layer 14 and the gas barrier supports 16, high durability can be exhibited.

[Optical Functional Layer]

As described above, the optical functional layer 12 is a layer exhibiting an optical function and is formed by; for example, dispersing or dissolving a substance in a matrix. For the optical functional layer 12, layers exhibiting various optical functions can be used. Specifically, examples thereof include a fluorescent layer (wavelength conversion layer), an organic electro luminescence layer (organic EL layer), a photoelectric conversion layer used in a solar cell or the like, and an image display layer of electronic paper or the like.

In the present invention, the optical functional layer 12 is preferably a fluorescent layer formed by dispersing a large number of phosphors in a matrix of resin or the like and has a function of converting the wavelength of light incident on the optical functional layer 12 to emit light.

In the functional film 10 shown in the drawing, as a more preferable aspect, the optical functional layer 12 is a quantum dot layer formed by dispersing quantum dots in a binder which becomes a matrix. Accordingly, for example, in a case where blue light emitted a backlight not shown in the drawing is incident on the optical functional layer 12, the optical functional layer 12 converts the wavelength of at least a part of the blue light into red light or green light by the effect of the phosphors contained therein and emits light.

<Quantum Dot and Quantum Rod>

A quantum dot is a fine particle of a compound semiconductor having a size of several nm to several tens of nm and is at least excited by incidence exciting light to emit fluorescent light.

The quantum dot included in the optical functional layer 12 can include at least one quantum dot, or also two or more quantum dots having different emission properties. A known quantum dot includes a quantum dot (A) having a center emission wavelength in the wavelength range in the range of more than 600 nm to 680 nm, a quantum dot (B) having a center emission wavelength in the wavelength range in the range of more than 500 nm to 600 rim., and a quantum dot (C) having a center emission wavelength in the wavelength range in the range of 400 nm to 500 nm. The quantum dot (A) is excited by exciting light to emit red light, the quantum dot (B) is excited by exciting light to emit green light and the quantum dot (C) is excited by exciting light to emit blue light.

For example, in a case where blue light is incident as exciting light on an optical functional layer 12 including the quantum dots (A) and the quantum dot (B), white light can be can realized by red light emitted from the quantum dot (A), green light emitted from the quantum dot (B) and blue light penetrating through the optical functional layer. Alternatively, in a case where ultraviolet light can be incident as exciting light on a functional film having an optical functional layer 12 including the quantum dots (A), (B) and (C), white light can be can realized by red light emitted from the quantum dot (A), green light emitted from the quantum dot (B) and blue light emitted from the quantum dot (C).

With respect to the quantum dot, those described in, for example, paragraphs 0060 to 0066 in JP2012-169271A can be referenced, but the quantum dot is not limited to those. For the quantum dot, a commercially available product can be used without any limitation. The emission wavelength of the quantum dot can be usually adjusted by the composition and the size of a particle.

The optical functional layer 12 (quantum dot layer) is formed by using a polymerizable composition (coating solution) in which quantum dots are dispersed.

The content of the quantum dot may be appropriately set according to the kind of the quantum dot, the performance required for the functional film 10, and the like. Specifically, the quantum dot can be added in an amount of, for example, about 0.1 to 10 parts by mass with respect to 100 parts by mass of the total amount of the polymerizable composition.

The quantum dot may be added to the polymerizable composition in the form of a particle and may be added to the polymerizable composition in the form of a dispersion liquid in which the quantum dots are dispersed in an organic solvent. It is preferable to add the quantum dot in the form of a dispersion liquid from the viewpoint of suppressing aggregation of quantum dot particles. The organic solvent used to disperse the quantum dots is not particularly limited.

In the present invention, a quantum rod can be used instead of the quantum dot. The quantum rod is a particle having an elongated rod shape and has the same properties as those of the quantum dot. The amount of the quantum rod to be added and the method for adding the quantum rod to the polymerizable composition may be the same as the amount of the quantum dot and the method for adding the quantum dot, respectively. The quantum dot and the quantum rod can also be used in combination.

<Polymerizable Compound>

As described above, the optical functional layer 12 is formed by dispersing the quantum dots in a matrix formed of a cured resin. Such an optical functional layer 12 is formed by using the polymerizable composition in which the quantum dots are dispersed. Accordingly, the polymerizable composition contains a polymerizable compound (curable compound) which becomes a resin (binder) constituting the matrix in the optical functional layer 12.

The polymerizable compound forming the optical functional layer 12 exemplified below is suitably used for forming the resin layer 14. That is, a polymerizable composition obtained by removing the quantum dots from the polymerizable composition for forming the optical functional layer 12 exemplified below is also suitably used for forming the resin layer 14 which surrounds the end surfaces of the optical functional layer 12 described later.

In the present invention, as the polymerizable compound forming the optical functional layer 12 (resin layer 14), a polymerizable compound having a polymerizable group can be widely adopted. The kind of the polymerizable group is not particularly limited, and is preferably a (meth)acrylate group, a vinyl group or an epoxy group, more preferably a (meth)acrylate group, still more preferably, an acrylate group. In addition, with respect to a polymerizable compound having two or more polymerizable groups, the respective polymerizable groups may be the same or different.

<<(Meth)Acrylate-Based>>

From the viewpoint of transparency, adhesiveness and the like of a cured coating film after curing, a (meth)acrylate compound such as a monofunctional or polyfunctional (meth)acrylate monomer, a polymer or prepolymer thereof, or the like is preferable.

In the specification, the term “(meth)acrylate” is used to mean at least one or any one of acrylate and methacrylate. The same applies to the term “(meth)acryloyl” and the like.

<<<Bifunctional Monomer>>>

As a polymerizable compound having two polymerizable groups, for example, a bifunctional polymerizable unsaturated monomer having two ethylenically unsaturated. bond-containing groups can be used. The bifunctional polymerizable unsaturated monomer is suitable for allowing a composition to have a low viscosity. In the embodiment, a (meth)acrylate-based compound having excellent reactivity and having no problems such as a remaining catalyst is preferable.

in particular, neopentyl glycol di(meth)acrylate, 1,9-nonanediol di(meth)acrylate, dipropylene glycol di(meth)acrylate, tripropylene glycol di(meth)acrylate, tetraethylene glycol di(meth)acrylate, hydroxypivalate neopentyl glycol di(meth)acrylate, polyethylene glycol di(meth)acrylate, dicyclopentenyl(meth)acrylate, dicyclopentenyl oxyethyl(meth)acrylate, dicyclopentanyl di(meth)acrylate, or the like is suitably used in the present invention.

The amount of the bifunctional (meth)acrylate monomer to be used may be appropriately set according to the kind of the bifunctional (meth)acrylate monomer or the like. Specifically, the amount of the bifunctional (meth)acrylate monomer to be used is preferably 5 parts by mass or more, and more preferably 10 to 80 parts by mass with respect to 100 parts by mass of the total amount of the polymerizable compound included in the polymerizable composition, from the viewpoint that the viscosity of the polymerizable composition is adjusted in a preferable range.

<<<Tri- or Higher Functional Monomer>>>

As a polymerizable compound having three or more polymerizable groups, for example, a polyfunctional polymerizable unsaturated monomer having three or more ethylenically unsaturated bond-containing groups can be used. The polyfunctional polymerizable unsaturated monomer is preferable from the viewpoint of imparting mechanical strength. In the embodiment, a (meth)acrylate-based compound having excellent reactivity and having no problem of a residual catalyst is preferable.

Specifically, epichlorohydrin (ECH)-modified glycerol tri(meth)acrylate, ethylene oxide (EO)-modified glycerol tri(meth)acrylate, propylene oxide (PO)-modified glycerol tri(meth)acrylate, pentaerythritol triacrylate, pentaerythritol tetraacrylate, EO-modified phosphoric acid triacrylate, trimethylolpropane tri(meth)acrylate, caprolactone-modified trimethylolpropane tri(meth)acrylate, EO-modified trimethylolpropane tri(meth)acrylate, PO-modified trimethylolpropane tri(meth)acrylate, tris(acryloxyethyl)isocyanurate, dipentaaerythritol hexa(meth)acrylate, dipentaaerythritol penta(meth)acrylate, caprolactone-modified dipentaaerythritol hexa(meth)acrylate, dipentaaerythritol hydroxy penta(meth)acrylate, alkyl-modified dipentaaerythritol penta(meth)acrylate, dipentaaerythritol poly(meth)acrylate, alkyl-modified dipentaaerythritol tri(meth)acrylate, ditrimethylolpropane tetra(meth)acrylate, pentaerythritol ethoxy tetra(meth)acrylate, or pentaerythritol tetra(meth)acrylate is suitable.

Among these, in particular, EO-modified glycerol tri(meth)acrylate, PO-modified glycerol tri(meth)acrylate, trimethylolpropane tri(meth)acrylate, EO-modified trimethylolpropane tri(meth)acrylate, PO-modified trimethylolpropane tri(meth)acrylate, dipentaaerythritol hexa(meth)acrylate, dipentaaerythritol penta(meth)acrylate, pentaerythritol ethoxy tetra(meth)acrylate, or pentaerythritol tetra(meth)acrylate is suitably used in the present invention.

The amount of the polyfunctional (meth)acrylate monomer to be used may be appropriately set according to the kind of the polyfunctional (meth)acrylate monomer or the like. Specifically, the amount of the polyfunctional (meth)acrylate monomer to be used is preferably 5 parts by mass or more from the viewpoint of the coating film hardness of the optical functional layer after curing, and preferably 95 parts by mass or less from the viewpoint of suppression of gelation of the polymerizable composition, with respect to 100 parts by mass of the total amount of the polymerizable compound included in the polymerizable composition.

<<<Monofunctional Monomer>>>

As the monofunctional (meth)acrylate monomer, acrylic acid and methacrylic acid, and derivatives thereof, more specifically, a monomer having one polymerizabie unsaturated bond ((meth)acryloyl group) of (meth)acrylic acid in one molecule maybe used. Specific examples thereof include the following compounds, but the present embodiment is not limited thereto.

Examples thereof include alkyl(meth)acrylates having 1 to 30 carbon atoms in the alkyl group, such as methyl(meth)acrylate, n-butyl(meth)acrylate, isobutyl(meth)acrylate, 2-ethylhexyl(meth)acrylate, isobornyl(meth)acrylate, n-octyl(meth)acrylate, lauryl(meth)acrylate and stearyl(meth)acrylate; aralkyl(meth)acrylates having 7 to 20 carbon atoms in the aralkyl group, such as benzyl(meth)acrylate; alkoxyalkyl(meth)acrylates having 2 to 30 carbon atoms in the alkoxyalkyl group, such as butoxy-ethyl(meth)acrylate; aminoalkyl(meth)acrylates having 1 to 20 carbon atoms in total in the (monoalkyl or dialkyl)aminoalkyl group, such as N,N-dimethylaminoethyl(meth)acrylate; polyalkylene glycol alkyl ether(meth)acrylates having 1 to 10 carbon atoms in the alkylene chain and having 1 to 10 carbon atoms in the terminal alkyl ether, such as diethylene glycol ethyl ether(meth)acrylate, triethylene glycol butyl ether(meth)acrylate, tetraethylene glycol monomethyl ether(meth)acrylate, hexaethylene glycol monomethyl ether(meth)acrylate, octaethylene glycol monomethyl ether(meth)acrylate, nonaethylene glycol monomethyl ether(meth)acrylate, dipropylene glycol monomethyl ether(meth)acrylate, heptapropylene glycol monomethyl ether(meth)acrylate and tetraethylene glycol monoethyl ether(meth)acrylate; polyalkylene glycol aryl ether(meth)acrylates having 1 to 30 carbon atoms in the alkylene chain and having 6 to 20 carbon atoms in the terminal aryl ether, such as hexaethylene glycol phenyl ether(meth)acrylate; (meth)acrylate having an alicyclic structure and having 4 to 30 carbon atoms in total, such as cyclohexyl(meth)acrylate, dicyclopentanyl(meth)acrylate, isobornyl(meth)acrylate and methylene oxide addition cyclodecatriene(meth)acrylate; fluorinated alkyl(meth)acrylates having 4 to 30 carbon atoms in total, such as heptadecafluorodecyl(meth)acrylate;(meth)acrylates having a hydroxyl group, such as 2-hydroxyethyl(meth)acrylate, 3-hydroxypropyl(meth)acrylate, 4-hydroxybutyl(meth)acrylate, triethylene glycol mono(meth)acrylate, tetraethylene glycol mono(meth)acrylate, hexaethylene glycol mono(meth)acrylate, octapropylene glycol mono(meth)acrylate and glycerol mono or di(meth)acrylate; (meth)acrylates having a glycidyl group, such as glycidyl(meth)acrylate; polyethylene glycol mono(meth)acrylates having 1 to 30 carbon atoms in the alkylene chain, such as tetraethylene glycol mono(meth)acrylate, hexaethylene glycol mono(meth)acrylate and octapropylene glycol mono(meth)acrylate; and (meth)acrylamides such as (meth)acrylamide, N,N-dimethyl(meth)acrylamide, N-isopropyl(meth)acrylamide, 2-hydroxyethyl(meth)acrylamide and acryloylmorpholine.

The amount of the monofunctional (meth)acrylate monomer to be used may be appropriately set according to the kind of the monofunctional (meth)acrylate monomer or the like. Specifically, the amount of the monofunctional (meth)acrylate monomer to be used is preferably 10 parts by mass or more, and more preferably 10 to 80 parts by mass with respect to 100 parts by mass of the total amount of the polymerizable compound included in the polymerizable composition, from the viewpoint of adjusting the viscosity of the polymerizable composition in a preferable range.

<<Epoxy-Based Compound and Others>>

As the polymerizable compound forming the optical functional layer 12 (resin layer 14), a compound having a cyclic group such as a ring-opening polymerizable cyclic ether group such as an epoxy group and an oxetanyl group may be used.

As such a compound, more preferably, a compound (epoxy compound) having an epoxy group may be used. By using the compound having an epoxy group or an oxetanyl group in combination with the (meth)acrylate-based compound, adhesiveness with the gas harrier support 16 is likely to be improved.

Examples of the compound having an epoxy group can include polyglycidyl esters of polybasic acid, polyglycidyl ethers of polyhydric alcohol, polyglycidyl ethers of polyoxyalkylene glycol, polyglycidyl ethers of aromatic polyol, hydrogenated compounds of polyglycidyl ethers of aromatic polyol, urethane polyepoxy compounds, and epoxidized polybutadienes. These compounds can be used alone or as a mixture of two or more.

Examples of other compound having an epoxy group, which can be preferably used, can include aliphatic cyclic epoxy compounds, bisphenol A diglycidyl ethers, bisphenol F diglycidyl ethers, bisphenol S diglycidyl ethers, brominated bisphenol A diglycidyl ethers, brominated bisphenol F diglycidyl ethers, brominated bisphenol S diglycidyl ethers, hydrogenerated bisphenol A diglycidyl ethers, hydrogenerated bisphenol F diglycidyl ethers, hydrogenerated bisphenol S diglycidyl ethers, 1,4-butanediol diglycidyl ethers, 1,6-hexanediol. diglycidyl ethers, glycerin triglycidyl ethers, trimethylolpropane triglycidyl ethers, polyethylene glycol diglycidyl ethers and polypropylene glycol diglycidyl ethers; polyglycidyl ethers of polyether polyol, obtained by adding one, or two or more alkylene oxides to an aliphatic polyhydric alcohol such as ethylene glycol, propylene glycol or glycerin; diglycidyl esters of aliphatic long chain dibasic acid; monoglycidyl ethers of aliphatic higher alcohol; monoglycidyl ethers of polyether alcohol, obtained by adding an alkylene oxide to phenol, cresol., butyl phenol or these phenols; and glycidyl esters of higher fatty acid,

Among these components, aliphatic cyclic epoxy compounds, bisphenol A diglycidyl ethers, bisphenol F diglycidyl ethers, hydrogenerated bisphenol A diglycidyl ethers, hydrogenerated bisphenol F diglycidyl ethers, 1,4-butanediol diglycidyl ethers, 1,6-hexanediol diglycidyl ethers, glycerin triglycidyl ethers, trimethylolpropane triglycidyl ethers, neopentyl glycol diglycidyl ethers, polyethylene glycol diglycidyl ethers, and polypropylene glycol diglycidyl ethers are preferable.

Examples of a commercially available product, which can be suitably used as the compound having an epoxy group or an oxetanyl group, include UVR-6216 (manufactured by Union Carbide Corporation), glycidol, AOEX24, CYCLOMER A200, CELLOXIDE 2021P and CELLOXIDE 8000 (these manufactured by Daicel Corporation), 4-vinylcyclohexene dioxide manufactured by Sigma Aldrich, EPIKOTE 828, EPIKOTE 812, EPIKOTE 1031, EPIKOTE 872 and EPIKOTE CT508 (these manufactured by Yuka Shell Epoxy K.K.), and KRM-2400, KRM-2410, KRM-2408, KRM-2490, KRM-2720 and KRM-2750 (these manufactured by Adeka Corporation). These can be used alone or in a combination of two or more.

In addition, regarding these compounds having an epoxy group or an oxetanyl group, any production method thereof may he adopted and the compounds having an epoxy group or an oxetanyl group can be synthesized with reference to Literatures such as Fourth Edition Experimental Chemistry Course 20 Organic Synthesis II, p. 213, 1992, published by Maruzen KK; Ed. by Alfred Hasfner, The chemistry OF heterocyclic compounds-Small Ring Heterocycles part 3 Oxiranes, John & Wiley and Sons, An Interscience Publication, New York, 1985, Yoshimura, Bonding, vol. 29, No. 12, 32, 1985, Yoshimura, Bonding, vol. 30, No. 5, 42, 1986, Yoshimura, Bonding, vol. 30, No. 7, 42, 1986, JP1999-100378A (JP-HU-100378A), JP2906245B, and JP2926262B.

As the polymerizable compound forming the optical functional layer 12 (resin layer 14), a vinyl ether compound may also be used.

As the vinyl ether compound, a known vinyl ether compound can be appropriately selected, and, for example, one described in paragraph 0057 in JP2009-73078A can he preferably adopted.

These vinyl ether compounds can be synthesized by, for example, the method described in Stephen. C. Lapin, Polymers Paint Colour Journal. 179 (4237), 321 (1988), namely, by a reaction of a polyhydric alcohol or a polyhydric phenol with acetylene, or a reaction of a polyhydric alcohol or a polyhydric phenol with a halogenated alkyl vinyl ether, and such method and reactions can be used alone or in combination of two or more.

For the polymerizable composition for forming the optical functional layer 12 (resin layer 14), a silsesquioxane compound having a reactive group described in JP2009-73078A can also be used from the viewpoint of a decrease in viscosity and an increase in hardness.

The amount of the compound having an epoxy group, the vinyl ether compound, and the like to be used may be appropriately set according to the kind of the polymerizable compound and the like.

<Thixotropic Agent>

The polymerizable composition for forming the optical functional layer 12 (resin layer 14) may contain a thixotropic agent.

The thixotropic agent is an inorganic compound or an organic compound.

<<Inorganic Compound>>

One preferable aspect of the thixotropic agent is a thixotropic agent of an inorganic compound, and, for example, a needle-like compound, a chain-like compound, a flattened compound or a layered compound can be preferably used. Among these, a layered compound is preferable.

The layered compound is not particularly limited, and examples thereof include talc, mica, feldspar, kaolinite (kaolin clay), pyrophyllite (pyrophyllite clay), sericite, bentonite, smectite and vermiculite (montmorillonite, beidellite, non-tronite, saponite and the like), organic bentonite, and organic smectite.

These can be used alone or in a combination of two or more. Examples of a commercially available layered compound include, as inorganic compounds, Crown Clay, Burgess Clay #60, Burgess Clay KF and OptiWhite (these manufactured by Shiraishi Kogyo Kaisha Ltd.), Kaolin JP-100, NN Kaolin Clay, ST Kaolin Clay and Hardsil (these manufactured by Tsuchiya Kaolin Ind., Ltd.), ASP-072, Satintonplus, Translink 37 and Hydrousdelami NCD (these manufactured by Angel Hard Corporation), S Y Kaolin, O S Clay, H A Clay and M C Hard Clay (these manufactured by Maruo Calcium Co., Ltd.), Rucentite SWN, Rucentite SAN, Rucentite STN, Rucentite SEN and Rucentite SPN (these manufactured by Co-op Chemical Co., Ltd.), Swnecton (manufactured by Kunimine Industries Co., Ltd.), Bengel, Bengel F W, Esben, Esben 74, Organite and Organite T (these manufactured by Hojun Co., Ltd.), Hodaka Jirushi, Orben, 250M, Bentone 34 and Bentone 38 (these manufactured by Wilbur-Ellis Company), and Laponite, Laponite RD and Laponite RDS (these manufactured by Nippon Silica Industrial Co., Ltd.). These compounds may also be dispersed in a solvent.

The thixotropic agent to be added to the polymerizable composition is, among layered inorganic compounds, a silicate compound represented by xM(I)₂O·ySiO₂ (also including a compound corresponding to M(II)O or M(III)₂O₃ having an oxidation number of 2 or 3; x and y represent a positive number), and a further preferable compound is a swellable layered clay mineral such as hectorite, bentonite, smectite or vermiculite.

Particularly preferably, a layered (clay) compound modified by an organic cation (a silicate compound in which an interlayer cation such as sodium is exchanged with an organic cation compound) can be suitably used, and examples thereof include sodium magnesium silicate (hectorite) in which a sodium ion is exchanged with an ammonium ion described below.

Examples of the ammonium ion include a monoalkyltrimethylammonium ion, a dialkyldimethylammonium ion and a trialkylmethylammonium ion having an alkyl chain having 6 to 18 carbon atoms, a dipolyoxyethylene-palm-oil-alkylmethylammonium ion and a bis(2-hydroxyethyl)-palm-oil-alkylmethylammonium ion having 4 to 18 oxyethylene chains, and a polyoxypropylene methyldiethylammonium ion having 4 to 25 oxopropylene chains. These ammonium ions can be used alone or in a combination of two or more.

The method for producing an organic cation-modified silicate mineral in which a sodium ion of sodium magnesium silicate is exchanged with an ammonium ion is such that sodium magnesium silicate is dispersed in water and sufficiently stirred, and thereafter left to still stand for 16 hours or more to adjust a 4% by mass dispersion liquid. While this dispersion liquid is stirred, a desired ammonium salt is added in an amount of 30% by mass to 200% by mass relative to sodium magnesium silicate. After the addition, cation exchange occurs to allow hectorite including an ammonium salt between layers to be insoluble in water and precipitated, and thus the precipitate is taken by filtration and dried. In the preparation, heating may also be performed for the purpose of accelerating the dispersion.

A commercially available product of the alkyl:ammonium-modified silicate mineral includes Rucentite SAN, Rucentite SAN-316, Rucentite STN, Rucentite SEN and Rucentite SPN (these manufactured by Co-op Chemical Co., Ltd.), and these can be used alone or in a combination of two or more.

In the embodiment, silica, alumina, silicon nitride, titanium dioxide, calcium carbonate, zinc oxide or the like can be used for the thixotropic agent of an inorganic compound. Such a compound can also he if necessary subjected to a treatment for regulation of hydrophilicity or hydrophobicity of the surface.

<<Organic Compound>>

For the thixotropic agent, a thixotropic agent of an organic compound can be used.

Examples of the thixotropic agent of an organic compound include an oxidized polyolefin and a modified urea.

The above-oxidized polyolefin may he independently prepared, or a commercially available product may be used. Examples of the commercially available product include DISPERLON 4200-20 (manufactured by Kusumoto Chemicals, Ltd.) and FLOWNON SA300 (manufactured by Kyoeisha Chemical Co., Ltd.).

The modified urea described above is a reaction product of an isocyanate monomer or an adduct thereof with an organic amine. The modified urea described above may be independently prepared or a commercially available product may be used. Examples of the commercially available product include BYK 410 (manufactured by BYK Japan K.K.).

The content of the thixotropic agent is preferably 0.15 to 20 parts by mass, more preferably 0.2 to 10 parts by mass, and particularly preferably 0.2 to 8 parts by mass with respect to 100 parts by mass of the polymerizable compound in the polymerizable composition. In particular, in a case of the thixotropic agent of an inorganic compound, brittleness tends to be improved at a content of 20 parts by mass or less with respect to 100 parts by mass of the polymerizable compound

<Polymerization Initiator>

The polymerizable composition for forming the optical functional layer 12 (resin layer 14) may contain a polymerization initiator.

As the polymerization initiator, the polymerizable composition may include a polymerization initiator. With respect to the polymerization initiator, for example, paragraph 0037 in JP2013-043382A can be referred to.

The amount of the polymerization initiator is preferably 0.1% by mol or more and more preferably 0.5% to 2% by mol with respect to total amount of the polymerizable compound included in the polymerizable composition. In addition, the amount of the polymerization initiator is preferably 0.1% to 10% by mass and more preferably 0.2% to 8% by mass as the percentage by mass in the entire curable composition excluding the volatile organic solvent.

<Silane Coupling Agent>

The polymerizable composition for forming the optical functional layer 12 (resin layer 14) may contain a silane coupling agent.

The optical functional layer 12 formed of the polymerizable composition including the silane coupling agent can exhibit excellent durability because of being strong in adhesiveness to an adjacent layer due to the silane coupling agent.

In addition, in a case where the silane coupling agent has a reactive functional group such as a radical polymerizable group, formation of a crosslinking structure with a monomer component constituting the optical functional layer can also contribute to improvement in adhesiveness to the adjacent layer to the optical functional layer.

For the silane coupling agent, a known silane coupling agent can be used without any limitation. A preferable silane coupling agent in terms of adhesiveness can include a silane coupling agent represented by Formula (1) described in JP2013-43382A.

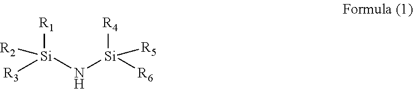

(In Formula (1), R₁ to R₆ each independently represent a substituted or unsubstituted alkyl group or aryl group. Herein, at least one of R₁ to R6 represents a substituent including a radical polymerizable carbon-carbon double bond.)

R₁ to R₆ each preferably represent an unsubstituted alkyl group or an unsubstituted aryl group except for a case where R₁ to R₆ represent a substituent including a radical polymerizable carbon-carbon double bond. The alkyl group is preferably an alkyl group having 1 to 6 carbon atoms, and more preferably a methyl group. The aryl group is preferably a phenyl group. R₁ to R₆ each particularly preferably represent a methyl group.

At least one of R₁ to R₆ has a substituent including a radical polymerizable carbon-carbon double bond, and two of R₁ to R₆ preferably have a substituent including a radical polymerizable carbon-carbon double bond. Furthermore, it is particularly preferable that one of R₁ to R₃ has a substituent including a radical polymerizable carbon-carbon double bond and one of R₄ to R₆ has a substituent including a radical polymerizable carbon-carbon double bond.

In a case where the silane coupling agent represented by Formula (1) has two or more substituents including a radical polymerizable carbon-carbon double bond, the respective substituents may be the same or different, and are preferably the same.

It is preferable that the substituent including a radical polymerizable carbon-carbon double bond is represented by —X—Y. Herein, X represents a single bond, an alkylene group having 1 to 6 carbon atoms, or an arylene group, preferably represents a single bond, a methylene group, an ethylene group, a propylene group or a phenylene group. Y represents a radical polymerizable carbon-carbon double bond group, preferably an acryloyloxy group, a methacryloyloxy group, an acryloylamino group, a methacryloylamino group, a vinyl group, a propenyl group, a vinyloxy group or a vinylsulfonyl group, and more preferably a (meth)acryloyloxy group.

R₁ to R6 may also have a substituent other than the substituent including a radical polymerizable carbon-carbon double bond. Examples of such a substituent include alkyl groups (such as a methyl group, an ethyl group, an isopropyl group, a tert-butyl group, a n-octyl group, a n-decyl group, a n-hexadecyl group, a cyclopropyl group, a cyclopentyl group and a cyclohexyl group), aryl groups (such as a phenyl group and a naphthyl group), halogen atoms (such as fluorine, chlorine, bromine and iodine), acyl groups (such as an acetyl group, a benzoyl group, a formyl group and a pivaloyl group), acyloxy groups (such as an acetoxy group, an acryloyloxy group and a methacryloyloxy group), alkoxycarbonyl groups (such as a methoxycarbonyl group and an ethoxycarbonyl group), aryloxycarhonyl groups (such as a phenyloxycarbonyl group), and sulfonyl groups (such as a methanesulfonyl group and a benzenesulfonyl group).

The content of the silane coupling agent in the polymerizable composition may be appropriately set according to the kind of the silane coupling agent used, the composition of the polymerizable composition, the configuration of the gas barrier support 16, and the like. From the viewpoint of further improvement in adhesiveness to the adjacent layer, the content of the silane coupling agent is preferably 1% to 30% by mass, more preferably 3 to 30% by mass, and particularly preferably 5% to 25% by mass.

The thickness of the optical functional layer 12 may be appropriately set according to the kind of the optical functional layer 12, the size of the functional film, and the like. The thickness of the optical functional layer 12, that is, the size of the optical functional layer 12 in a direction of lamination of the optical functional layer 12 and the gas barrier support 16. Regarding this point, the same applies to the resin layer 14 and the gas barrier support 16.

As described above, since the optical functional layer 12 is a quantum dot layer, the thickness thereof is to be appropriately designed according to the intensity and the wavelength of incidence excitation, the concentration of the quantum dot used, the emission quantum efficiency, and an optical system to be assembled. Typically, the thickness of the optical functional layer 12, that is, the thickness of the quantum dot layer is preferably 10 to 3,000 μm, more preferably 20 to 1,000 μm, and particularly preferably 30 to 500 μm.

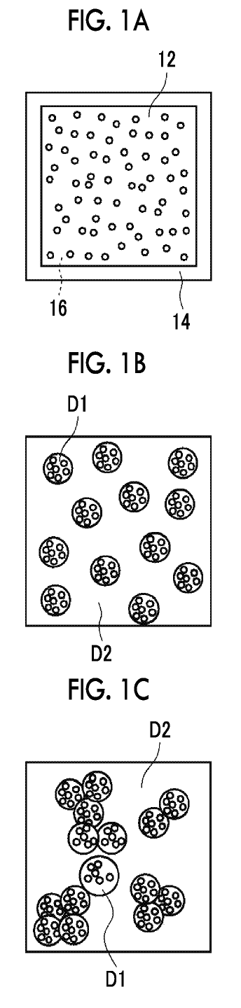

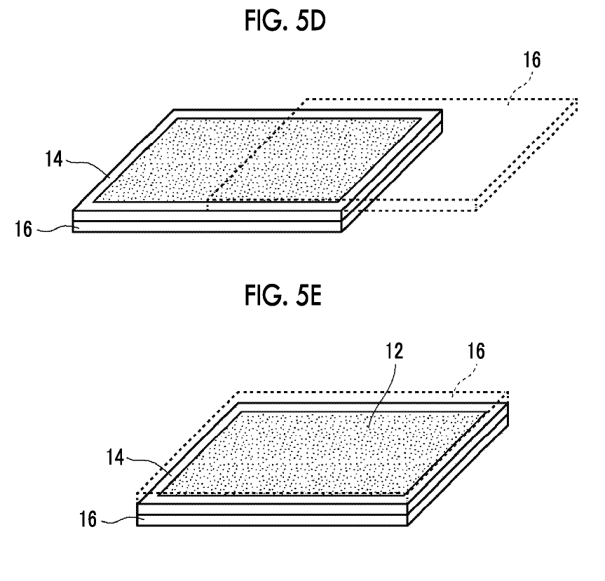

The planar shape of the optical functional layer 12 is not particularly limited and various shapes such as a rectangular sheet shape, a rectangular strip shape, a circular shape and an elliptical shape can be used. For example, the optical functional layer 12 shown in the drawing has a rectangular shape as conceptually shown in FIGS. 1A and 5E and the like.

The planar shape of the optical functional layer 12 is the primary surface shape and is a shape in a direction orthogonal to the primary surface, that is, a shape as FIG. 2 is viewed from above. That is, FIGS. 1A to 1C are all plan views (top views).

[Resin Layer]

The functional film 10 is configured such that the resin layer 14 is formed so as to surround the end surfaces (side edge portions) of the optical functional layer 12. In other words, the optical functional layer 12 is formed so as to be accommodated in the inside of the frame-shaped resin layer 14.

As described above, the resin layer 14 prevents the intrusion of oxygen or the like from the end surface of the optical functional layer 12 by sealing the end surfaces of the optical functional layer 12. That is, the resin layer 14 is provided for preventing deterioration of the quantum dot by the intrusion of oxygen into the optical functional layer 12 from the end surface thereof.

Accordingly, it is preferable that the resin layer 14 has low oxygen permeability. Specifically, the oxygen permeability of the resin layer 14 is 10 cc/(m²·day·atm) or less and preferably 1 cc/(m²·day·atm) or less. The oxygen permeability of the resin layer 14 used herein means the oxygen permeability of the resin layer 14 in a width direction.

By setting the oxygen permeability of the resin layer 14 to 10 cc/(m²·day·atm) or less, deterioration of the quantum dot of the optical functional layer 12 by oxygen can be prevented for a longer period of time.

As the SI unit of oxygen permeability, it is known that there is fm/(s·Pa). The oxygen permeability can be converted into 1 fm/(s·Pa)=8.752 cc/(m²·day·atm). The term “fm” means fermtometer.

In the present invention, the oxygen permeability may be a value measured using an oxygen gas permeability measuring apparatus (OX-TRAN 2/20, manufactured by MOCON Inc.) under the conditions of a measurement temperature of 23° C. and a relative humidity of 90%.

In addition, as a method for measuring the oxygen permeability of the resin layer 14, for example, a method including forming a resin film having the same width and the same thickness as the resin layer 14 with the same material as the resin layer 14, and measuring the oxygen permeability of the resin sheet is exemplified. In a case where the resin sheet having the same thickness as the resin layer 14 is difficult due to a problem in film formation, a value obtained by converting a difference in thickness from the actually measured value of oxygen permeability that can be obtained by forming a resin sheet having a thickness at which a film can be formed may be used instead.

The width of the resin layer 14 refers to the size of the resin layer 14 in a longitudinal direction of the resin layer 14 or in a direction orthogonal to the tangent of the resin layer 14 in a plane direction of the optical functional layer 12 (gas barrier support 16). That is, the width of the resin layer 14 is the size of the resin layer 14 in the longitudinal direction of the resin layer 14 or in the direction orthogonal to the tangent of the resin layer 14 in a direction orthogonal to the thickness.

In addition, in the present invention, by providing such a resin layer 14, the thickness of the optical functional layer 12 is reduced and the degree of freedom of selection of the polymerizable compound (resin) for forming the optical functional layer 12 and the resin layer 14 is improved.

As shown in US2015/0047765A, according to a quantum dot layer in which a domain D1 formed of a hydrophobic resin including quantum dots is formed in a domain D2 formed of a hydrophilic resin having low oxygen permeability, it is possible to prevent deterioration of the quantum dot caused by oxygen (refer to FIG. 1B or the like).

However, since the domain D2 is continuously formed in the configuration in which the resin layer (domain D2) which is provided to prevent the deterioration of the quantum dot caused by oxygen is provided in the optical functional layer as described above, it is required to increase the relative amount of the resin forming the domain D2 and thus the film thickness of the quantum dot layer is increased. Further, the kind of material that allows a combination of the domain D1 in which the dispersion stability of the quantum dots is good and the domain D2 is limited and further the emission quantum yield of the quantum dots depends on a difference in refractive index between the resins forming the two domains. Thus, the degree of freedom of resin selection is not high.

In contrast, in the functional film 10 of the present invention in which the optical functional layer 12 is surrounded by the frame-shaped resin layer 14, it is not required to provide the resin layer for preventing the deterioration of the quantum dots in the optical functional layer 12. Thus, the amount of the resin is not required to be increased for forming a continuous phase. As a result, the thickness of the optical functional layer 12 can be reduced.

Further, since the optical functional layer 12 is formed of one resin, it is not required to consider the mutual dispersion stability of a plurality of kinds of resins and a difference in reflective index between resins. Accordingly, the optical functional layer 12 and the resin layer 14 are not related to each other and the resin (polymerizable composition) may be selected according to required properties. Thus, the degree of freedom of resin selection is high. In addition, since the design of an additive for securing the dispersion stability of the quantum dots is freely carried out, the quantum dots can sufficiently exhibit predetermined performance.

In addition, as described above, since the resin layer 14 is provided so as to surround the end surfaces of the optical functional layer 12, deterioration of the quantum dot by the intrusion of oxygen into the optical functional layer 12 from the end surface can be prevented.

The advantages of the present invention are described in the description and the use of the optical functional layer material which allows the optical functional layer 12 to have a phase-separated structure as shown in FIG. 1B is not limited. As described above, various materials can be appropriately used for the optical functional layer 12 according to purposes.

For the resin layer 14, layers of various known resins can be used.

Accordingly, the resin layer 14 may be formed by curing a polymerizable compound capable of forming a resin that exhibits required gas barrier properties. Among these, it is preferable to form the resin layer 14 by using the resin (binder) obtained by curing the polymerizable compound exemplified in the above-described optical functional layer 12. That is, it is preferable to form the resin layer 14 by using a polymerizable composition excluding the quantum dots from the polymerizable composition exemplified in the optical functional layer 12.

The thickness of the resin layer 14 may be appropriately set according to the forming material of the resin layer 14, the thickness and the forming material of the optical functional layer 12, and the like.

Here, the resin layer 14 and the optical functional layer 12 to be combined have a function of laminating the pair of gas barrier supports 16. Accordingly, from the viewpoint of preventing intrusion of air bubbles at the time of peeling-off and lamination during use, the thicknesses of the resin layer 14 and the optical functional layer 12 are preferably substantially the same. That is, it is preferable that a difference between the thickness of the resin layer 14 and the thickness of the optical functional layer 12 is small.

The difference between the thickness of the resin layer 14 and the thickness of the optical functional layer 12 used herein refers to “difference in thickness (%)” obtained by calculating a value (thickness) obtained from an average thickness value for the entire regions of the respective resin layer 14 and optical functional layer 12 by the following equation.

(Difference in thickness (%)=|(thickness of optical functional layer)−(thickness of resin layer)|÷(thickness of optical functional layer)×100

In consideration of the above point, a difference in thickness of the functional film 10 of the present invention is within 30% and preferably within 20%.

The thickness can be obtained by cutting the functional film 10 with a rnicrotorne in a cross-sectional direction and observing the cross section with an optical microscope (for example, ECLIPSE LV100PCL manufactured by Nikon Corporation).

The width of the resin layer 14 may be appropriately set according to the size of the functional film 10 in the plane direction, the required area of the optical functional layer 12, and the like.

Herein, the width of the resin layer 14 is preferably 0.5 mm or more and more preferably 1 mm or more. In a case where the width of the resin layer 14 is set to 0.5 mm or more, sufficient barrier properties can be imparted and thus this case is preferable.

The upper limit of the width of the resin layer 14 is not particularly limited but it is preferable to minimize the region in which the resin layer 14 is provided as much as possible. For example, in a case where the functional film 10 is used as a wavelength conversion plate to be mounted in an LCD backlight module, an LED package, and an LED array for monitors or for mobile phones, the width of the resin layer 14 is preferably 5 mm or less and more preferably 3 mm or less.

As described above, in the functional film 10 of the present invention, the optical functional layer 12 includes a cured product of the polymerizable compound as a binder. In the optical functional layer 12, the binder becomes a matrix in which the quantum dots are dispersed.

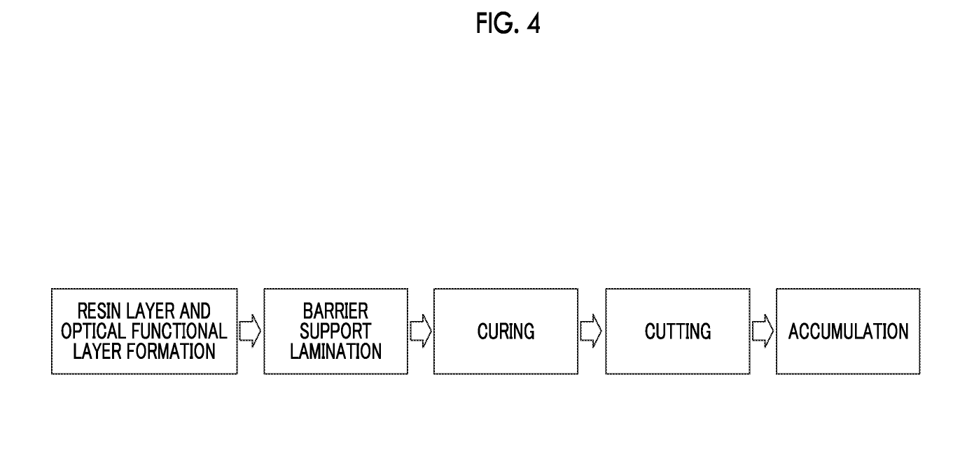

Herein, as conceptually shown in FIG. 3, it is preferable to form a binder infiltrated layer 14a by infiltration of the binder (polymerizable compound) of the optical functional layer 12 into the resin layer 14 in the functional film 10. In other words, it is preferable to form the binder infiltrated layer 14a in such a manner that the polymerizable compound for forming the optical functional layer 12 is infiltrated into and cured on the resin layer 14.

By forming the binder infiltrated layer 14a by infiltration of the binder forming the optical functional layer 12 into the resin layer 14, the resin layer 14 and the optical functional layer 12 are caused to firmly adhere to each other by a covalent bond and thus peeling—off between the resin layer 14 and the optical functional layer 12 and formation of air bubbles between the layers due to a shrinkage force generated during the curing reaction of the polymerizable compound forming the optical functional layer 12, and peeling-off between the resin layer 14 and the optical functional layer 12 and formation of air bubbles between the layers due to internal stress generated by heat or light at the time of using the functional film 10 can be prevented in advance.

In the method for producing the functional film 10 of the present invention, as described later, the resin layer 14 is provided and then the optical functional layer 12 is provided. Therefore, in a case where the polymerizable composition for forming the optical functional layer 12 includes a polymerizable compound, a part of the polymerizable compound is infiltrated into the resin layer 14.

The present inventors have assumed that by this infiltration, the polymerizable compound is incorporated into a network of the polymer constituting the resin layer 14 formed in advance and an interpenetrating polymer network is formed during the curing reaction (polymer network formation) of the optical functional layer 12, that is, the binder infiltrated layer 14a is formed so that a strong bond is formed.

On the other hand, the excessive infiltration of the polymerizable compound into the resin layer 14 provides a plasticizing effect on the resin constituting the resin layer 14 and thus there is a concern of causing deterioration in the sealing performance of the end portion.

In addition, the formation width of the hinder infiltrated layer 14a on the resin layer 14 has the optimal range. The width of the binder infiltrated layer 14a refers to a width of the binder infiltrated layer 14a in the same direction as the above-described width of the resin layer 14.

In consideration of the above point, the width of the binder infiltrated layer 14a is preferably 0.01 to 10 μm and more preferably 0.02 to 5 μm. In this range, both good interlaminar adhesion between the optical functional layer 12 and the resin layer 14 and the effect of keeping good performance of the resin layer 14 can be suitably obtained.

Regarding whether or not the binder infiltrated layer 14a is formed, the presence and the width thereof can be confirmed by cutting the functional film 10, cutting the cross section across the resin layer 14 and the optical functional layer 12, and mapping a change in the element distribution by SEM-EDX or mapping the fragment distribution of the resin using a TOE-SIMS method.

The width of the binder infiltrated layer 14a is preferably calculated with the maximum intrusion width (the change point of the element distribution or the limit at which the fragment of the binder is detected) in the cross section.

The functional film 10 may have an inorganic layer that covers the outer end surface (outer surface) of the resin layer 14. The outer end surface of the resin layer 14 refers to a surface directed to the outside of the laminate excluding surfaces directed to the gas barrier support 16 and the optical functional layer 12 in the resin layer 14.

By providing such an inorganic layer, the gas barrier properties of the resin layer 14 can be increased.

The inorganic layer to he formed on the outer end surface of the resin layer 14 will be described in detail later.

[Gas Barrier Support]

The functional film 10 of the present invention has a configuration in which such an optical functional layer 12 and the resin layer 14 that surrounds the end surfaces of the optical functional layer 12 are sandwiched between the pair of gas barrier supports 16 so that the primary surface of the optical functional layer 12 is interposed therebetween.

The gas barrier support 16 has barrier properties with respect to oxygen and water vapor. The functional film 10 of the present invention has the gas barrier support 16 for sealing the primary surface of the optical functional layer 12 in addition to the above-described resin layer 14 for sealing the end surface of the optical functional layer 12. Thus, the functional film 10 exhibiting predetermined performance for a long period of time can be realized by preventing the deterioration of the quantum dots of the optical functional layer 12 by oxygen and water vapor.

In the present invention, the gas barrier support 16 may be rigid or flexible.

In addition, it is preferable that the gas barrier support 16 is transparent with respect to visible light as described later since the gas barrier support is a path for light incident on or emitted from the functional film 10 of the present invention.

The expression “transparent to visible light” here refers to a light transmittance in the visible light region, of 80% or more. In addition, as the higher the light transmittance of the gas barrier support 16 in the visible light region is, the more preferable it is. The light transmittance is preferably 85% or more and more preferably 90% or more.

The visible light region refers to a wavelength range of 380 to780 am. In addition, the light transmittance can be calculated according to the method described in JIS-K7105, that is, by measuring the total light transmittance and the amount of light to be scattered, by use of an integrating sphere light transmittance measuring apparatus, and subtracting the diffuse transmittance from the total light transmittance.

In order to suppress quantum dot deterioration of the optical functional layer 12 by oxygen or the like, the gas barrier support 16 preferably has low oxygen permeability.

Specifically, the oxygen permeability of the gas barrier support 16 is preferably 0.1 cc/(m²·day·atm) or less. The lower the oxygen permeability of the gas barrier support 16 is, the more preferable it is. The oxygen permeability is more preferably 0.01 cc/(m²·day·atm) or less and particularly preferably 0.001 cc/(m²·day·atm) or less.

By setting the oxygen permeability of the gas barrier support 16 to 0.1 cc/(m²·day·atm) or less, the deterioration of the quantum dots of the optical functional layer 12 by oxygen or the like can be prevented for a longer period of time.

For the gas barrier support 16, as long as the gas barrier support has desired gas barrier properties, various sheet-shaped materials or films (gas barrier films) formed of inorganic material such as glass or quartz glass, resin, and a composite thereof can be used.

Specifically, suitable examples of the resin film include plastic films of polyethylene (PE), polyethylene naphthalate (PEN), polyamide (PA), polyethylene terephthalate (PET), polyvinyl chloride (PVC), polyvinyl alcohol (PVA), polyacrylonitrile (PAN), polyimide (PI), transparent polyimide, a polymethacrylic acid methyl resin (PMMA), polycarbonate (PC), polyacrylate, polymethacrylate, polypropylene (PP), polystyrene (PS), ABS, a cyclic olefin-copolymer (COC), a cycloolefin polymer (COP), and triacetyl cellulose (TAC).

With respect to the resin film, paragraphs 0046 to 0052 in JP2007-290369A and paragraphs 0040 to 0055 in JP2005-096108A can be referred to.

In addition, tier example, a commercially available product such as COSMOSHINE A4100 manufactured by Toyobo Co., Ltd., which is a polyethylene terephthalate (PET) film with an easily adhesive layer, can be used as the resin film that becomes the gas barrier support 16.

Further, as the gas barrier support 16, a gas barrier film formed by using the resin film as a base material and having an inorganic layer exhibiting gas barrier properties formed therein can be suitably used.

Hereinafter, an inorganic layer exhibiting barrier properties to be provided on the gas barrier support 16 is also referred to as “barrier inorganic layer” for the sake of convenience.

In such a gas barrier film, the thickness of the resin film which becomes a base material may be appropriately set according to the thickness required for the functional film 10, the size of the functional film 10 in the plane direction, the kind of the resin film, and the like. Specifically, from the viewpoint of gas barrier properties, impact resistance, and the like, the thickness of the resin film which becomes a base material is preferably 10 to 500 μm, more preferably 15 to 300 μm, still more preferably 15 to 120 μm, even still more preferably 15 to 110 μm, even further more preferably 25 to 110 μm, and particularly preferably 25 to 60 μm.

The barrier inorganic layer is a layer having an inorganic material (inorganic compound) as a main component and is preferably a layer formed of only an inorganic material. The expression “layer formed of only an inorganic material” also includes a case where inevitably mixed impurities are present.

The inorganic material constituting the barrier inorganic layer is not particularly limited and for example, metal and various inorganic compounds such as inorganic oxide, nitride, and oxynitride can be used.

As elements constituting the inorganic compound, silicon, aluminum, magnesium, titanium, tin, indium, and cerium are preferable and one or two or more of these may be contained. Specific examples of the inorganic compound include silicon oxide, silicon oxynitride, aluminum oxide, magnesium oxide, titanium oxide, tin oxide, indium oxide alloy, silicon nitride, aluminum nitride, and titanium nitride.

In addition, as the barrier inorganic layer, a metal film, for example, a titanium film, a copper film, an aluminum film, a silver film, a tin film, a chromium film, or a nickel film can be suitably used.

Among these, it is preferable that the barrier inorganic layer is an inorganic layer including at least one compound selected from silicon nitride, silicon oxynitride, silicon oxide, or aluminum oxide. Among these, from the viewpoint of transparency and gas harrier properties, silicon nitride is suitably used for the barrier inorganic layer.

The barrier inorganic layer formed of these materials has good adhesiveness with the organic layer described later. Thus, even in a case where the inorganic layer has pinholes, the organic layer can effectively fill the pinholes and fractures can be suppressed. In addition, a very good barrier inorganic layer film can be formed in a case where a plurality of inorganic layers are laminated, and barrier properties can be further increased.

Regarding the thickness of the barrier inorganic layer, the thickness for obtaining required gas barrier properties may be appropriately set according to the forming material of the barrier inorganic layer and the like.

Specifically, the thickness of the barrier inorganic layer is preferably 1 to 500 nm, more preferably 5 to 300 μm, and particularly preferably 10 to 150 nm. By setting the film thickness of the barrier inorganic layer to be in the above range while realizing good barrier properties, light reflection by the barrier inorganic layer can be suppressed. Thus, a laminated film having a higher light transmittance can be provided.

One barrier inorganic layer or two or three or more barrier inorganic layers may be provided in the gas barrier support 16.

The barrier inorganic layer may be formed by known methods such as plasma chemical vapor deposition (CVD), sputtering, vacuum vapor deposition, and the like.

In the gas barrier support 16 in which the barrier inorganic layer is formed on the base material, an organic layer may be provided as a base layer of the barrier inorganic layer.

By providing the organic layer as the base layer of the barrier inorganic layer, a proper inorganic layer without cracks or defects can be entirely formed by adjusting the formation surface of the barrier inorganic layer. As a result, since the gas barrier support has the laminated structure of the organic layer and the barrier inorganic layer, the gas barrier properties of the gas barrier support 16 can be significantly improved.

The gas barrier support 16 may have only one combination of the base organic layer and the barrier inorganic layer or may have a plurality of combinations thereof.

It is preferable to laminate the plurality of combinations of the base organic layer and the barrier inorganic layer from the viewpoint of improving light resistance since the barrier properties can be further improved. On the other hand, as the number of layers to be laminated increases, the light transmittance of the optical functional layer is likely to decrease. Thus, it is desirable to increase the number of layers to be laminated in a range in which a good light transmittance can be maintained. Regarding this point, the same applies to a case where only the barrier inorganic layer is provided without the organic layer

The organic layer is a layer having an organic material as a main component and is a layer in which the content of the organic material preferably occupies 50% by mass or more, more preferably occupies 80% by mass or more, and particularly preferably occupies 90% by mass or more.

For the organic layer, descriptions in paragraphs 0020 to 0042 of JP2007-290369A and paragraphs 0074 to 0105 of JP2005-096108A can be referred to.

It is preferable that the organic layer contains a cardo polymer. Accordingly, the adhesiveness between the organic layer and the adjacent layer and, particularly, adhesiveness with the inorganic layer become excellent, and more excellent gas barrier properties can be realized. For the details of the cardo polymer, paragraphs 0085 to 0095 of JP2005-096108A described above can be referred to.

The thickness of the organic layer in the gas barrier support 16 may be appropriately set according to the forming material of the organic layer, the required thickness of the functional film 10, and the like.

Specifically, the thickness of the organic layer is preferably 0.05 to 10 μm and more preferably 0.5 to 10 μm. More specifically, in a case where the organic layer is formed by a coating method, the thickness of the organic layer is preferably 0.5 to 10 μm and more preferably 1 to 5 μm. In a case where the organic layer is formed by a dry coating method, the thickness of the organic layer is preferably 0.05 to 5 μm and more preferably 0.05 to 1 μm.

By setting the thickness of the organic layer formed by a coating method or a dry coating method in this range, more excellent adhesiveness between the organic layer and the barrier inorganic layer can be obtained.

In addition, the gas barrier support 16 may have an organic layer as the uppermost layer.

The organic layer of the uppermost layer functions as a protective layer for the barrier inorganic layer. By providing the organic layer as the uppermost layer, the barrier inorganic layer exhibiting gas barrier properties can be prevented from being damaged and the gas barrier support 16 can more stably exhibit desired gas barrier properties. In addition, by providing the organic layer as the uppermost layer, the adhesiveness between the optical functional layer 12 formed by dispersing quantum dots in the resin which becomes a matrix and the gas barrier support 16 can be improved.

Basically, the organic layer of the uppermost layer may be the same as the above-described organic layer which becomes the base of the barrier inorganic layer. In addition, for the organic layer of the uppermost layer, a layer of a graft copolymer having an acrylic polymer as a main chain and at least one of a urethane polymer having an acryloyl group at the terminal or a urethane oligomer having an acryloyl group at the terminal as a side chain, and having a molecular weight of 10000 to 3000000 and an acrylic equivalent of 500 g/mol or more in addition to the compounds exemplified in the base organic layer can he suitably used.

Regarding the barrier inorganic layer and the organic layer, in addition to the above description, the descriptions in JP2007-290369A, JP2005-096108A, and US2012/0113672A1 described above can be referred to.

In the functional film 10, in a case where the gas barrier support 16 has the barrier inorganic layer, it is preferable that at least one barrier inorganic layer directly in contact with the optical functional layer 12 is included. Further, in the case where the gas barrier support 16 has the barrier inorganic layer, it is more preferable that the barrier inorganic layers are directly in contact with both surfaces of the optical functional layer 12.

That is, in a case where the gas barrier support 16 has the base organic layer and the barrier inorganic layer, it is preferable that the barrier inorganic layer is provided on a side opposite to the base material instead of the organic layer. Accordingly, it is possible to prevent intrusion of oxygen, which has intruded from the end surface of the organic layer and the base material, into the optical functional layer 12 from the primary surface.

As described above, for the gas barrier support 16, glass and the like can he suitably used.

Specifically, for example, a transparent inorganic support of soda lime glass, borosilicate glass, or quartz can be used. More specifically, G-Leaf (trade name) which is long flexible ultra-thin plate glass that can be rolled around a roll and manufactured by Nippon Electric Glass Co., Ltd., commercially available glass sheets, and the like may be used. The thickness, the oxygen permeability, and the transparency thereof are preferably set to be in the above-described ranges of the gas barrier support.

In the functional film 10 of the present invention, in addition to the optical functional layer 12, the resin layer 14, and the gas barrier support 16, as needed, other functional layers can be provided.

Examples of such functional layer include a hard coat layer, an anti-Newton ring layer, a frictional force reduction layer, an antifouling layer, a cushion layer, an antireflection layer, a light diffusion layer, a prism layer, a microlens layer, a reflective polarizer layer, an absorbing polarizer layer, a wavelength selective reflection layer, a wavelength selective transmission layer, a light absorbing layer, a thermal conductive layer, and a heat radiating layer.

In addition, an inorganic layer, a light scattering layer, a light absorbing layer, a heat radiating layer, a thermal conductive layer, a hard coat layer, a cushion layer, and the like may be provided on the outer end surface of the resin layer 14 and a surface on which the outer end surface of the resin layer 14 and the end surface of the gas barrier support 16 are formed. In particular, as described later, an inorganic layer is preferably provided so as to cover the outer end surface of the resin layer 14.

[Method for Producing Functional Film]

Hereinafter, an example of a method for producing functional film 10 having a quantum dot layer as the optical functional layer 12 will be described.

—Production Method by Roll-to-Roll Process—

As the method for producing the functional film of the present invention, it is preferable to use a roll-to-roll process to produce the functional film. In the following description, the term “roll-to-roll process” is also referred to as “R to R process”.

In the R to R process, in the principle thereof, it is preferable to use the gas barrier support 16 using a flexible support.

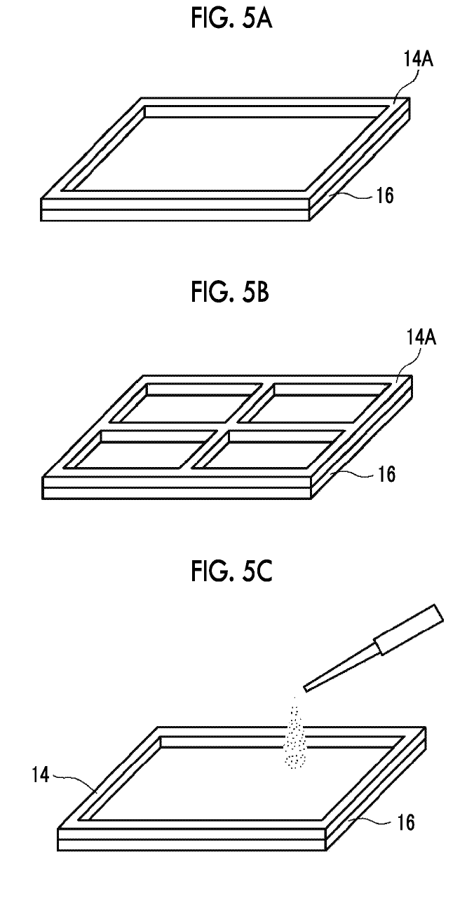

Hereinafter, with reference to FIG. 4, each step of the specific example thereof will be in order. These steps are preferably performed in the order described in the specification. As needed, the order of the steps can be appropriately changed or the same step can be performed multiple times. In addition, the production method shown in FIG. 4 can be used not only for R to R but also for a sheet-feed process (batch type process)

<Resin Layer and Optical Functional Layer Forming Step>

<<Preparation of Polymerizable Composition 1 and Polymerizable Composition 2>>

First, respective components of quantum dots (or quantum rods), a polymerizable compound, a thixotropic agent, a polymerization initiator, a silane coupling agent, and the like are mixed using a tank or the like and thus a polymerizable composition 1 for forming the optical functional layer 12 is prepared.

In addition, a resin having high barrier properties such as an epoxy-based resin is mixed with the composition using a tank and thus a polymerizable composition 2 for forming the resin layer 14 is prepared.

These polymerizable compositions may contain a volatile organic solvent or may not substantially contain a volatile organic solvent.

Here, the polymerizable composition not substantially containing a volatile organic solvent means that the ratio of the volatile organic solvent in the polymerizable composition is 10000 ppm or less,

In addition, the volatile organic solvent refers to a compound which has a boiling point of 160° C. or lower, is not cured by the polymerizable compound in the polymerizable composition and external stimulation, and is liquid at 20° C. The boiling point of the volatile organic solvent is 160° C. or lower, preferably 115° C. or lower, and more preferably 30° C. to 100° C.

<<Coating and Filling Step>>

While the long gas barrier support 16 is being transported in the longitudinal direction, a pattern is filled with the polymerizable composition 2 for forming the resin layer 14 supplied on a screen by a scraper, and is transferred to the gas barrier support 16 using a squeegee. Thus, a frame-shaped polymerizable composition 2 is formed on the surface of the gas barrier support 16. Subsequently, in a case where the polymerizable composition 2 contains a solvent, the solvent is evaporated.

Further, the polymerizabie composition 1 is transferred to or fills the inside of the polymerizable composition 2 for forming the resin layer 14 that is formed on the surface of the gas barrier support 16 using the squeeze by, while transporting the long gas barrier support 16 on which the resin layer 14 is formed in the longitudinal direction, filling the pattern with the polymerizable composition 1 for forming the optical functional layer 12 supplied on the screen by the scraper. Subsequently, in a case where the polymerizable composition 1 contains a solvent, the solvent is evaporated.

Here, in a case where the gas barrier support 16 has a barrier inorganic layer, it is preferable to form the resin layer 14 or the like on the surface on which the barrier inorganic layer is formed. In particular, as described above, it is more preferable that the surface of the gas barrier support 16 is set as the barrier inorganic layer and the resin layer 14 or the like is formed on the barrier inorganic layer. Regarding this point, the same applies to the production of the functional film by the sheet-feed method described later.

In the above method, a printing method is used as a coating method. However, instead of the printing method, an ink jet method or a dispenser method may be used.

<Lamination Step>

In a lamination step, by putting and nipping the other gas barrier support 16 that is transported while being rolled around a laminating roller and the gas barrier support 16 whose surface is coated with or filled with the polymerizable composition 2 and the polymerizable composition 1 and which is transported while being rolled around a backup roller between the laminating roller and the backup roller, the other gas barrier support 16 is laminated on the polymerizable composition which is applied or fills the surface of the gas barrier support 16.

Accordingly, since a laminated film having a three-layer structure in which a product formed by filling the inside of the frame-shaped polymerizable composition 2 with the polymerizable composition 1 is interposed between two gas barrier supports 16 is formed, a contact chance of the coating film and external air (oxygen in the external air) can be reduced. Thus, it is possible to suppress performance deterioration of the quantum dots included in the coating film by oxygen.

<Curing Step>

In a curing step, while the laminated film having a three-layer structure in which a product formed by filling the inside of the frame-shaped polymerizable composition 2 with the uncured polymerizable composition 1 is interposed between two gas barrier supports 16 is being continuously transported on the backup roller, actinic ray irradiation is performed by an actinic ray irradiation apparatus to cure the polymerizable composition 1 and the polymerizable composition 2 and the resin layer 14 and the optical functional layer 12 are formed. Thus, a functional film is formed.

In this method, since the curing step is performed on the backup roller, wrinkle formation can be prevented in the produced functional film.

<Cutting Step and Accumulation Step>

Through the above steps, a laminate in which the functional film is continuously, formed on the long gas barrier support 16 can be obtained. The obtained functional film is cut by a cutting machine and individual functional films 10 are formed and accumulated.

The cutting may be performed by a known method using a guillotine blade, a cutting blade, a die set blade, a laser blade, or the like.

—Production Method by Sheet-feed Process—

In the production of the functional film of the present invention, it is preferable to use a sheet-feed process to produce the functional film,

In the sheet-feed process, in the principle thereof, a rigid gas barrier support 16 may be used and the gas barrier support 16 using a flexible support may be used.

Hereinafter, each step of the specific example in which a rigid support is used will be described in order. These steps are preferably performed in the order described in the specification. As needed, the order of the steps can be appropriately changed or the same step can be performed multiple times. In addition, although the description is made on the assumption that the support is rigid, the present invention does not limit the use of a flexible support.

As the sheet-feed process, various methods can be used and examples of a preferable method include a dam filling method and an injection method.

—Dam Filling Method—

As conceptually shown in FIGS. 5A to 5E, a dam filling method is a method including causing the polymerizable composition for forming the optical functional layer 12 to flow into partitions in which the remaining surface sides surrounded by the resin layer 14 and one gas barrier support 16 are opened and then sealing the remaining one surfaces with the other gas barrier support 16 not to form a void.

<Polymerizable Composition Preparing Step>

The step of preparing the polymerizable composition 1 which becomes the optical functional layer 12 and the polymerizable composition 2 which becomes the resin layer 14 is the same as the step of preparing the polymerizable compositions in the above-described R to R process. As needed, the viscosity and the solid contents can be appropriately adjusted.

<Resin Layer Forming Step>

<<Coating Step>>

First, the polymerizable composition 2 for forming the resin layer 14 is applied to one gas barrier support 16 in a frame shape.

As shown in FIG. 5A, the polymerizable composition 2 may be provided so as to fringe the side edge portion of the gas barrier support 16 as a closed line and in a case where the functional film is cut later and separated into a plurality of functional films 10, as shown in FIG. 5B, the polymerizable composition may be provided such that partitions are provided on the gas barrier support 16. A reference symbol 14A is assigned to the applied polymerizable composition 2.

The polymerizable composition 2 may be applied by a coating method using a dispenser or an ink jet or may be applied using a printing method or a transfer method.

<<Curing Step>>

Next, the polymerizable composition 2 for forming the resin layer 14 is cured to form the resin layer 14.

The polymerizable composition 2 may be cured by evaporation of only the solvent or may be cured by appropriately combining self-setting, thermosetting, photocuring, and the like. From the viewpoint of reducing the required step time, photocuring using a photocurable material is preferably performed.

The curing reaction may be conducted until the reactive compound is completely consumed or may be conducted such that a trace amount of the reactive compound remains. From the viewpoint of reinforcing the adhesion between the resin layer 14 and the pair of gas barrier supports 16 in the lamination step described later, it is preferable that the curing reaction is conducted such that a trace amount of the reactive compound remains. Whether or not a trace amount of the reactive compound remains can be detected by checking the degree of disappearance of the absorption peak of the targeted reactive functional group with Fourier Transform-infrared Spectroscopy (FT-IR).

<Polymerizable Composition 1 Filling Step>

Next, as shown in FIG. SC, the regions partitioned by the resin layer 14 provided in advance are filled with the polymerizable composition 1 for forming the optical functional layer 12.

In this step, a predetermined amount of the polymerizable composition may be supplied to the partitions using a dispenser or an ink jet or a space surrounded by the gas harrier support, the resin layer 14, and a screen in the manner of screen printing may be filled with the polymerizable composition for forming the functional layer. As needed, removal of the contained solvent or the curing reaction may be performed after application of the polymerizable composition.

In the present invention, in order to control the degree of formation of the above-described binder infiltrated layer 14a that is formed by infiltration of the binder into the resin layer 14, the elapsed time from the completion of the filling step to the lamination step may be appropriately adjusted.

<Lamination Step and Curing Step>

Next, as shown in FIGS. 5D and SE, the polymerizable composition 1 for forming the optical functional layer 12 filled in the frame by the resin layer 14 provided on one gas barrier support 16, and the resin layer 14 are sealed with the other gas barrier support 16 so that the polymerizable composition and the resin layer are covered by the other gas barrier support. Thus, the gas barrier support 16 is laminated thereon. In FIGS. 5D and 5E, in order to clearly shown the configuration, the polymerizable composition 1 (optical functional layer 12) is denoted by a dot pattern and the other gas harrier support 16 is denoted by a broken line.

Accordingly; a laminate in which a product obtained by filling the inside of the frame-shaped resin layer 14 with the uncured polymerizable composition 1 is interposed between the pair of gas barrier supports 16 is formed.

In this state, by curing the uncompleted resin layer 14 and curing the polymerizable composition 1 so as to complete the curing reaction of the polymerizable composition 1 for forming the optical functional layer 12, the optical functional layer 12 sealed by the resin layer 14 and the pair of gas barrier supports 16 without a void is formed.

At the time of the completion of the curing step, it is preferable that the polymerizable compounds of the resin layer 14 and the optical functional layer 12 are completely consumed. That is, at the time of measurement with FT-1R, it is preferable that the absorption peak of the targeted reactive functional group is not detected from the resin layer 14 and the optical functional layer 12 as a significant amount.

In a case where sufficient adhesiveness can be secured, the curing step may be performed before the other gas barrier support 16 is laminated or the curing step may be performed before and after the other gas barrier support 16 is laminated.

<Cutting, Polishing and Accumulation Step>

The laminate obtained through the steps is cut by a cutting machine and the films are accumulated through polishing and chamfering treatment of the end surface, as needed.

For the cutting method, various known methods such the methods exemplified in the R to R process can be used.

—Injection Method—

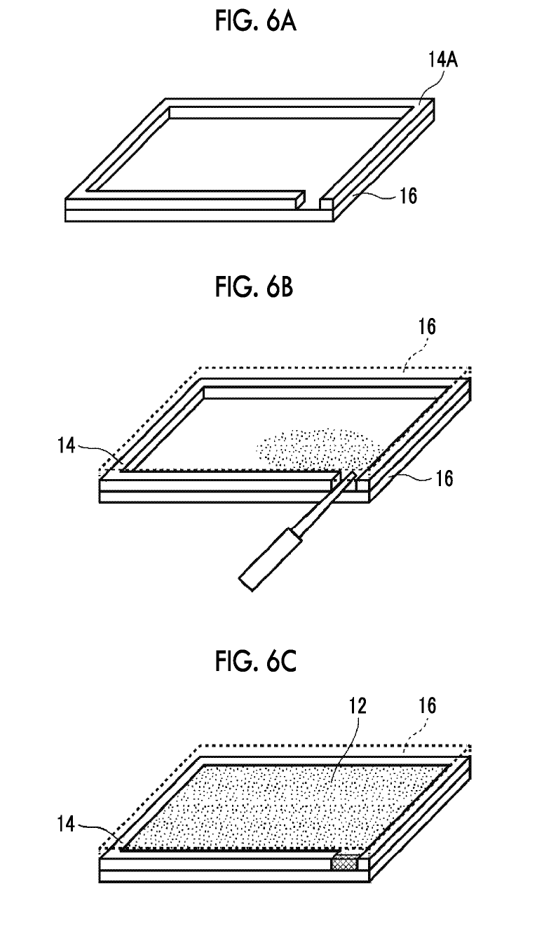

As conceptually shown in FIGS. 6A to 6C, an injection method is a method including causing the polymerizable composition for forming the optical functional layer 12 to flow into a cell-shaped partition surrounded by the resin layer 14 and the pair of gas barrier supports 16 and having an opening for injection provided in a part of the resin layer 14 and then sealing the opening for injection without leaving a void.

<Polymerizable Composition Preparing Step>

The step of preparing the polymerizable composition 1 which becomes the optical functional layer 12 and the polymerizable composition 2 which becomes the resin layer 14 is the same the same as the step of preparing the polymerizable compositions in the above-described R to R process. As needed, the viscosity and the solid contents can be appropriately adjusted.

<Resin Layer Forming Step and Lamination Step>

<<Coating Step>>

First, as shown in FIG. 6A, the polymerizable composition 2 which becomes the resin layer 14 is applied to the surface of one gas barrier support 16 in a frame shape. As in the dam filing method, the coating film of the polymerizable composition 2 may be provided to fringe the side edge portion of the gas barrier support 16 as a closed line (refer to FIG. 5A), or in a case where the functional film is cut later and separated into a plurality of functional film laminates, the polymerizable composition may be provided such that partitions are provided on the gas barrier support (refer to FIG. 5B). A reference symbol 14A is assigned to the applied polymerizable composition 2.

At this time, as shown in FIG. 6A, an opening for injection for the polymerizable composition 1 which becomes the optical functional layer 12 is provided.

In the coating step, the polymerizable composition may be applied by using a dispenser or an ink jet or may be applied using a printing method or a transfer method.

<<Lamination Step>>

Next, one gas barrier support 16 is laminated on the polymerizable composition 2 which becomes the resin layer 14 to form a cell-shaped partition (refer to FIG. 6B).

In FIGS. 6B and 6C, in order to clearly shown the configuration, the polymerizable composition 1 (optical functional layer 12) is denoted by a dot pattern and the other gas barrier support 16 is denoted by a broken line.

<<Curing Step>>

Then, the polymerizable composition 2 is cured to form the resin layer 14.

The polymerizable composition may be cured by evaporation of only the solvent or may be cured by appropriately combining self-setting, thermosetting, photocuring, and the like.

<Polymerizable Composition 1 Filling Step>

Next, as shown in FIG. 6B, the region partitioned by the formed resin layer 14 and the pair of gas barrier supports 16 is filled with the polymerizable composition 1 for forming the optical functional layer 12 from an opening portion formed in the resin layer 14.

In this step, a predetermined amount of the polymerizable composition may he supplied in the partition using a dispenser or the like or a method, called a vacuum injection method, in which the inside of the partition is tilled with the polymerizable composition for forming the functional layer using the negative pressure of the inside of the partition by immersing the opening portion in the polymerizable composition 2 in a state in which the inside of the partition is vacuumed, and then returning the outside to the atmospheric pressure, may be used.

<Curing Step>

After the inside of the region partitioned by the resin layer 14 and the gas barrier supports 16 filled with the polymerizable composition 1 for forming the optical functional layer 12, in this state, the curing reaction is conducted so that the curing reaction of the polymerizable composition 1 for forming the optical functional layer 12 is completed. Accordingly, the optical functional layer 12 sealed by the resin layer 14 and the pair of gas barrier supports without a void is formed.

At the time of the completion of the curing step, it is preferable that the reactive compounds of the resin layer 14 and the functional layer are completely consumed. In order to adjust the formation state of the binder infiltrated layer as a feature of the present invention, the elapsed time from the coating step to the curing reaction can be appropriately adjusted.

<Cutting and. Polishing Step>

After the curing step of curing the polymerizable composition 1 for forming the optical functional layer 12 is completed, the functional film is cut by a cutting machine and the films are accumulated through polishing and chamfering treatment of the end surface, as needed.

<Sealing Step>

Finally, as indicated by hatching in FIG. 6C, the opening for injecting the polymerizable composition 1 for forming the optical functional layer 12, which is formed in the resin layer 14, is sealed and thus a functional film is formed.

The opening may be sealed by a known method, for example, sealing using a resin having high gas barrier properties that may he used for the resin layer 14, sealing using a metal material such as solder, a method of attaching the above-described gas barrier support to the sealing region with a pressure sensitive adhesive or an adhesive, or a combination thereof.

In addition, the sealing may be performed with the formation of the end surface inorganic layer described later. This point will be described later.

[Inorganic Layer of Outer End Surface of Resin Layer]

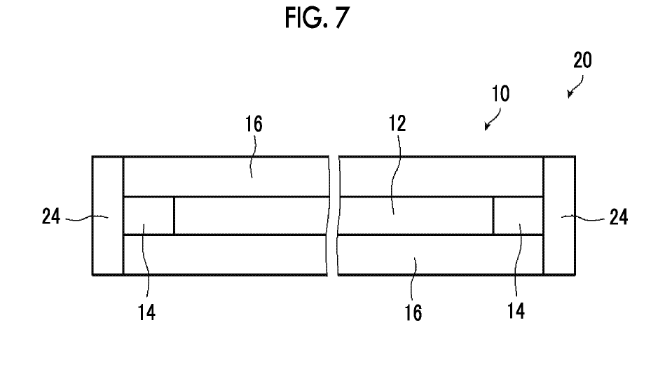

In the present invention, as in a functional film 20 shown in FIG. 7, an inorganic layer 24 may be provided to cover the outer end surface of the resin layer 14 of the functional film 10. Hereinafter, the inorganic layer 24 that is provided on the outer end surface of the resin layer 14 is referred to as “end surface inorganic layer 24” for the sake of convenience.

By providing such an end surface inorganic layer 24, oxygen or the like intruding into the optical functional layer 12 from the end surface of the functional film 10 is more suitably suppressed and further the deterioration of the quantum dots by oxygen or the like can be prevented for a long period of tune.

The forming material of the end surface inorganic layer 24 is not particularly limited and various inorganic materials exemplified in the barrier inorganic layer of the above-described gas barrier support 16 can he used.

Among these, from the viewpoint of obtaining a reduced thickness and excellent gas barrier properties, an end surface inorganic layer 24 formed of metal is suitably used.

The end surface inorganic layer 24 may have a single layer or may have a multilayer structure of two or three layers.

In a case where the end surface inorganic layer 24 has a multilayer structure, all layers may be formed of the same inorganic material or all layers may be formed of different inorganic materials. Further, in a case of three or more layers, layers formed of the same inorganic material and a layer formed of a different inorganic material may be mixed such that the first layer is formed of titanium, the second layer is formed of copper, and the third layer is formed of copper.

For the method for forming the end surface inorganic layer 24, any of coating, immersion, vapor deposition, sputtering, plating, soldering, and transferring can be used without any limitation. Among these, from the viewpoint that a dense inorganic layer without a gap can be provided, any of sputtering, vapor deposition, and plating is preferably used.

These methods can be used by applying various known production method of the related art.

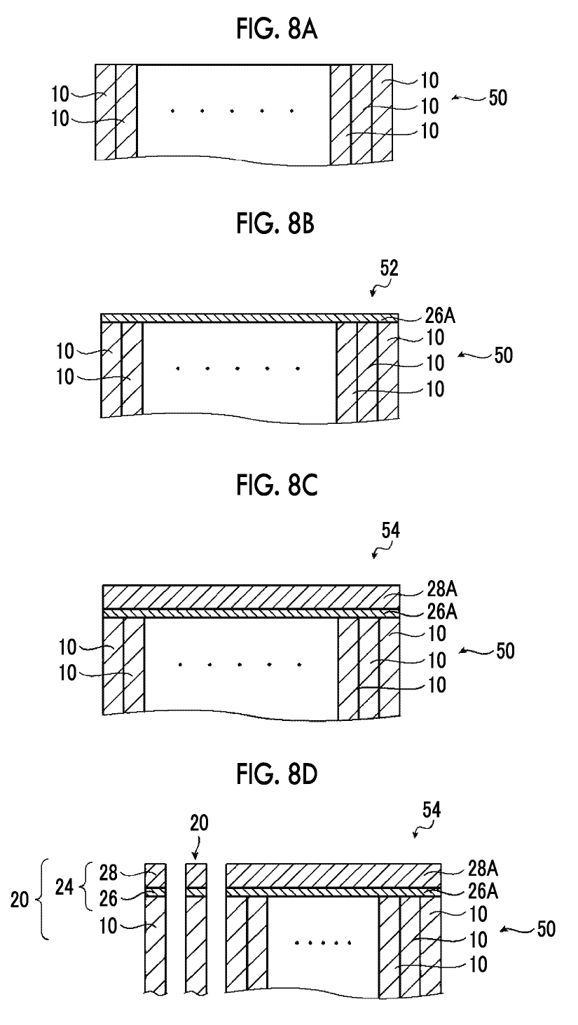

Hereinafter, with reference to the conceptual views of FIGS. 8A to 8B, an example of the method for forming the functional film 20 having the end surface inorganic layer 24 will be described.

In FIGS. 8A to 8D, as an example, the end surface inorganic layer 24 having a two-layer structure will be described. This production method makes it possible to exhibit high gas barrier properties at a small thickness and is most suitable for complementing gas barrier properties by applying the method to a portion of the resin layer 14 which cannot exhibit sufficient gas barrier properties inevitably for reasons of a width design.

First, as shown in FIG. 8A, the plurality of functional films 10 formed are superimposed to form a laminated product 50.

In the laminated product 50, the number of the functional films 10 is not particularly limited and may be appropriately set according to the size of an apparatus used for forming the end surface inorganic layer 24, the thickness of the functional film 10, and the like. Specifically, it is preferable to form a first end surface inorganic layer 26A by superimposing 500 to 4000 functional films 10.

Next, as shown in FIG. 8B, a first end surface inorganic layer 26A formed of an inorganic material is formed at the end surface of the laminated product 50.

As the forming material of the first end surface inorganic layer 26A, at least one selected from the group consisting of aluminum, titanium, chromium, copper, and nickel, or an alloy including at least one of these is suitably used.

For the method for forming the first end surface inorganic layer 26A, a sputtering method, a vacuum deposition method, an ion implanting method, electroless plating, a plasma CVD method, and the like are suitably used.

At the tune of formation of the first end surface inorganic layer 26A, the treatment method and the treatment conditions in a sputtering method, a vacuum deposition method, an ion implanting method, electroless plating, or a plasma CVD method are not particularly, limited and the first end surface inorganic layer 26A may be formed by a known treatment method and treatment conditions of the related art according to the forming material or the like.

In addition, by performing a masking treatment or the like by a known method in the region of the functional film 10 other than the end surface, that is, the region in which the first end surface inorganic layer 26A is not formed, the first end surface inorganic layer 26A may be formed on the end surface of the functional film 10.

Next, as shown in FIG. 8C, a second end surface inorganic layer 28A is formed on a first end surface inorganic layer 26A of a laminated product 52 in which the first end surface inorganic layer 26A is formed on the end surface.

As the forming material of the second end surface inorganic layer 28A, at least one selected from the group consisting of aluminum, titanium, chromium, nickel, tin, copper, silver and gold or an alloy including at least one of these is suitably used.

For the method for forming the second end surface inorganic layer 28A, it is preferable to use a plating treatment.

The treatment method and the treatment conditions of the plating treatment at the time of formation of the second end surface inorganic layer 28A are not particularly limited and the second end surface inorganic layer 28A may be formed by a known treatment method and treatment conditions of the related art according to the forming material or the like.

Next, as shown in FIG. 8D, a laminated product 54 in which the second end surface inorganic layer 28A is formed is separated into each functional film 10 and the functional film 20 having the end surface inorganic layer 24 having a two-layer structure formed by the first end surface inorganic layer 26 and the second end surface inorganic layer 28 is prepared on the end surface of the functional film 10.

The method for separating the functional film 20 from the laminated product 54 is not particularly limited and the functional film can be separated from the laminate by a shearing method of applying an external force, such as bending or twisting, to the laminated product 54 in which the second end surface inorganic layer 28A is formed in a horizontal direction to the surface, a method of inserting, fur example, a sharp tip end such as a cutter to the interface of the functional film 20, or the like.

From the viewpoint of preventing the occurrence of peeling-off, defects, and cracks in the end surface sealing layer or the like, it is preferable that the functional film 20 is separated from the laminate by shearing with an external force.

As described above, at the time of formation of each layer of the end surface inorganic layer 24, in a state in which the plurality of functional films 10 are superimposed, each layer of the end surface inorganic layer 24 can be formed. Accordingly, a plurality of functional films 20 can be collectively formed and thus high productivity can be obtained.

Here, at the time of formation of the end surface inorganic layer 24, the surface roughness Ra of the end surface of the functional film 10 is preferably 2.0 μm or less. By setting the surface roughness Ra of the end surface of the functional film 10 to 2.0 μm or less, the adhesiveness between the end surface of the functional film 10 and the end surface inorganic layer 24 can be further improved.

Such an end surface inorganic layer 24 may he formed to cover the entire end surface of the resin layer 14 (functional film 10) or may be formed to cover a part of the end surface of the resin layer 14.

However, in consideration of prevention of the deterioration of the quantum dots of the optical functional layer 12, it is preferable that the end surface inorganic layer 24 is formed to cover the entire end surface of the resin layer 14.

The formation of the end surface inorganic layer 24 is suitably used in a case where the production of the functional film 10 by the above-described injection method, the sealing portion of the opening portion for filing of the polymerizable composition 1 for forming the optical functional layer 12, which is provided in the resin layer 14, is more firmly sealed, or the like.

More specifically, the functional film 10 is prepared in a state in which the optical functional layer 12 is exposed from the opening portion, and then the injection port portion is sealed by sealing using the method.

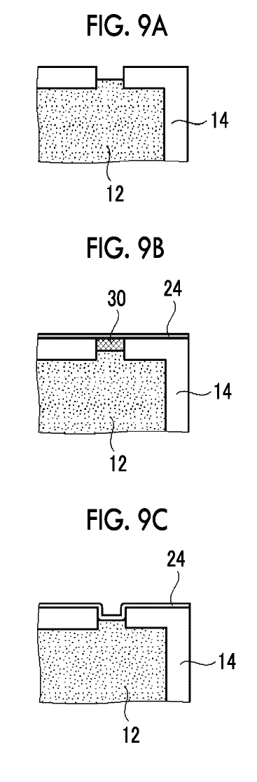

In the injection method, since injection without gap formation and overflowing caused by a change in the size of the partition and variation in the amount of injection accompanies technical difficulties, as conceptually shown in FIG. 9A, it is preferable that a gap is preferentially eliminated and slight overflowing is provided in the opening portion.

Accordingly, in a case where such an opening portion is sealed with only resin, the sealing width is reduced and sealing only at the injection port portion is weakened. In contrast, in a case of using, a sealing method in which the end surface inorganic layer 24 is combined with a sealing 30 with resin as conceptually shown in FIG. 9B, or a sealing method in which the opening portion is sealed only with the end surface inorganic layer 24 as conceptually shown in FIG. 9C, this problem is solved.

However, in the functional film of the present invention, easiness to degradation by oxygen is different according to the functional material contained in the optical functional layer 12.

Therefore, the gas barrier support 16 is not limited to the gas barrier film obtained by forming a gas barrier layer having barrier properties to oxygen or the like as the base material.

However, in a case in which the functional material contained in the optical functional layer 12 is the quantum dot of the embodiment, it is preferable to use the gas barrier film for at least one of the gas barrier supports 16 between which the optical functional layer 12 and the resin layer 14 are sandwiched.

### EXAMPLES

Hereinafter, the present invention will be described in more detail with reference to examples. However, the present invention is not limited to these examples and materials, amounts to be used, proportions, treatment contents, treatment procedures and the like shown. In examples below can be appropriately changed without departing from the gist of the present invention.

Polymerizable compositions for forming the following gas barrier support and optical functional layer and a polymerizable composition for forming the resin layer were prepared.

<Gas Barrier Support>

The gas barrier supports 16 were prepared in the following manner.

<<Base Material>>

As the base material of the gas barrier support 16, a PET film (trade name: COSMOSHINE A4300, manufactured by Toyobo Co., Ltd., thickness: 50 μm, width: 1000 mm, length: 100 m) was used.

<<Formation of Organic Layer>>

An organic layer was formed on one surface of the base material in the following manner.

First, a composition for forming an organic layer was prepared. Specifically, trimethylolpropane triacrylate (TMPTA, manufactured by Daicel-Cytec Co., Ltd.) and a photopolymerization initiator (ESACUREKTO46, manufactured by Lamberti SpA,) were prepared, weighed so that the mass ratio of TMPTA: photopolymerization initiator was 95:5, and dissolved in methyl ethyl ketone to prepare a composition having a solid content concentration of 15%.

The composition was used to form an organic layer on one surface of the base material by a general film formation apparatus for performing film formation by a coating method using a R to R process.

First, the composition was applied to one surface of the base material using a die coater. The base material after coating was allowed to pass through a drying zone at 50° C. for 3 minutes and then the composition was irradiated with ultraviolet light (cumulative amount of radiation: about 600 mJ/cm²) and cured to form the organic layer.

In addition, a polyethylene film (PE film, trade name: PAC2-30-T, manufactured by Sun A. Kaken Co., Ltd.) as a protective film was attached on the surface of the organic layer at a pass roll immediately after the ultraviolet light curing, transported and rolled.

The thickness of the formed organic layer was 1 μm.

<<Formation of Inorganic Layer>>

Next, a R to R type CVD apparatus was used to form an inorganic layer (silicon nitride (SiN) layer) on the surface of the organic layer.

The base material on which the organic layer was formed was fed from a feeding machine and passed through the final film surface touch roll before film formation of the inorganic layer, and then the protective film was peeled off to form an inorganic layer on the exposed organic layer by plasma CVD.

For formation of the inorganic layer, a silane gas (flow rate: 160 seem), an ammonia gas (flow rate: 370 seem), a hydrogen gas (flow rate: 590 seem) and a nitrogen gas (flow rate: 240 sccm) were used as raw material gases. A high-frequency power source with a frequency of 13.56 MHz was used as a power source. The film formation pressure was 40 Pa.

The formed film thickness was 50 nm.

<<Formation of Organic Layer>>

Further, an organic layer was laminated on the surface of the inorganic layer in the following manner.

First, a composition for forming an organic layer was prepared. Specifically, a urethane-bond-containing acrylic polymer (ACRIT 8BR500, manufactured by TAISEI FINE CHEMICAL CO., LTD, mass average molecular weight: 250,000), and a photopolymerization initiator (IRGACURE 184, manufactured by BASF SE) were prepared, weighed so that the mass ratio of urethane-bond-containing acrylic polymer: photopolymerization initiator was 95:5, and dissolved in methyl ethyl ketone to prepare a composition having a solid content concentration of 15% by mass.

The composition was used to form an organic layer on the surface of the inorganic layer by a general film formation apparatus for performing film formation by a coating method using a R to R process.

First, the composition was applied to one surface of the inorganic layer using a die coater. The base material after coating was allowed to pass through a drying zone at 100° C. for 3 minutes to form the organic layer.

Accordingly, a long gas barrier support 16 was prepared by forming the organic layer, the inorganic layer, and the organic layer on the base material. The thickness of the formed organic layer was 1 μm.

The same polyethylene film as described above as a protective film was attached to the surface of the organic layer in the gas barrier support 16 at a pass roll immediately after the composition for forming the organic layer of the uppermost surface was dried and then rolled.

The oxygen permeability of the prepared gas barrier support 16 was measured under the conditions of a measurement temperature of 23° C. and a relative humidity of 90% using an oxygen gas permeability measuring apparatus (OX-TRAN 2/20, manufactured by MOCON Inc.). As a result, it could be confirmed that the oxygen permeability of the gas barrier support 16 was 1×10⁻² cc/(m²·day·atm) or less.

<Preparation of Polymerizable Composition for Forming Optical Functional

A quantum dot dispersion liquid having the following composition was prepared and used as a polymerizable composition for forming an optical functional layer.
Dispersion liquid of quantum dot 1 in toluene (emission maximum: 520 nm) 10 parts by mass
Dispersion liquid of quantum dot 2 in toluene (emission maximum: 630 nm) 1 part by mass
Lauryl methacrylate 2.4 parts by mass
Trimethylolpropane triacrylate 0.54 parts by mass
Photopolymerization initiator (IRGACURE 819 (manufactured by BASF SE)) 0.009 parts by mass

For quantum dots 1 and 2, the following nanocrystals having a core-shell structure (InP/ZnS) were used.
Quantum dot 1: INP530-10 (manufactured by y NN-Labs, LLC)
Quantum dot 2: INP620-10 (manufactured by y NN-Labs, LLC)

<<Solvent Evaporation Step>>

The prepared quantum dot dispersion liquid was supplied to a tank and stirring was performed with a stirrer while supplying a nitrogen gas. Dissolved oxygen in the polymerizable composition was substituted by the nitrogen gas and thus the amount of the dissolved oxygen in the polymerizable composition was controlled to 1000 ppm or less. Then, toluene as a solvent was evaporated to 10000 ppm or less by reducing the pressure in the tank, and thus a polymerizable composition for forming an optical functional layer was prepared.

The viscosity of the prepared polymerizabie composition was 50 mPa·s.

<Preparation of Polymerizable Composition for Forming Resin Layer>

A polymerizable composition having the following composition was prepared.
Epoxy resin (composition obtained by mixing MAXIVEM-100 and C-93 at a ratio of 5:16, manufactured by MITSUBISHI GAS CHEMICAL COMPANY) 50 parts by mass
n-Butanol 50 parts by mass

### Example 1

The prepared long gas barrier support 16 was cut and thus two gas barrier supports 16 having a size of 5 cm square were prepared.

The protective film was peeled off from one gas barrier support 16 and the polymerizable composition for forming a resin layer was applied to the entire end portion of the surface of the organic layer in a frame shape by screen printing. Further, the polymerizable composition for forming an optical functional layer was applied to the inside of the frame by screen printing.

The polymerizable composition was dried at 80° C. for 10 minutes, then the protective film was peeled off from the other gas barrier support 16, and the organic layer was laminated toward the polymerizable composition. The polymerizable composition was cured by being irradiated with ultraviolet light from the coated surface at an irradiation dose of 1000 mJ/cm² using an air cooling metal halide lamp (manufactured by EYE GRAPHICS CO., LTD.) of 200 W/cm and further thermally cured by heating at 80° C. for 10 minutes to prepare a functional film 10.

In the prepared functional film 10, the width of the resin layer 14 was 3 mm, the thickness of the optical functional layer 12 and the resin layer 14 was 50 μm.

On the other hand, the polymerizable composition for forming the resin layer was applied to the PET film used in the gas barrier support 16 as the base material with an applicator and dried at 80° C. for 10 minutes. Then, the polymerizable composition was cured by being irradiated with ultraviolet light from the coated surface at an irradiation dose of 1000 mJ/cm² using an air cooling metal halide lamp (manufactured by EYE GRAPHICS CO,, LTD.) of 200 W/cm and further thermally cured by heating at 80° C. for 10 minutes. Then, the PET film was peeled off and removed to prepare a resin sheet having a thickness of 3 mm.

The oxygen permeability of the resin sheet was measured under the conditions of a measurement temperature of 23° C. and a relative humidity of 90% using an oxygen gas permeability measuring apparatus (OX-TRAN 2/20, manufactured by MOCON Inc.). As a result, the oxygen permeability of the resin sheet, that is, the oxygen permeability of the resin layer 14 was 0.4 cc/(m²·day·atm).

### Examples 2 to 4 and Comparative Examples 1 to 3

Functional films 10 were prepared in the same manner as in Example 1 except that the width of the resin layer 14 was changed to 1 mm (Example 2), 0.5 mm (Example 3), 0 mm (Comparative Example 1), and 0.1 mm (Comparative Example 3). That is, Comparative Example 1 is an example in which the functional film was prepared by applying only the optical functional layer without providing the resin layer 14.

The oxygen permeability of the resin layer 14 was measured in the same manner as in Example 1. As a result, the oxygen permeability of the resin layer 14 was 1.2 cc/(m²·day·atm) in Example 2, 2.4 cc/(m²·day·atm) in Example 3, and 12 cc/(m²·day·atm) in Comparative Example 3, respectively

Further, functional films 10 were prepared in the same manner as in Example 1 except that the thickness of the resin layer 14 was 40 μm (Example 4) and 30 μm (Comparative Example 2).

### Examples 5 to 9

Laminated films were prepared in the same manner as in Example 1 except that before the solvent in the polymerizable composition was dried at 80° C. for 10 minutes in Example 1, aging was performed for 2 minutes (Example 5), 5 minutes (Example 6), 10 minutes (Example 7), and 30 minutes (Example 8) under nitrogen purge at room temperature, respectively.

In addition, a laminated film of Example 9 was prepared in the same manner as in Example 1 except that the polymerizable composition which became the resin layer 14 was provided by screen printing and then baked at 80° C. for 30 minutes to remove the solvent and to completely thermally cure the resin layer 14, the polymerizable composition which became the optical functional layer was then applied by screen printing again, the polymerizable composition which became the resin layer 14 was further applied to the resin layer 14 such that the thickness after drying was 1 μm, and the other gas barrier support was laminated without aging.

### Example 10

A functional film 10 was prepared by the above-described dam tilling method.

As the gas barrier supports 16, two sheets of B270 glass with an optically polished surface having a thickness of 500 μm and a size of 5 cm square, manufactured by Schott AG, were prepared.

The polymerizable composition for forming the resin layer was applied to the entire end portion of one gas barrier support 16 using a dispenser and baked at 80° C. for 15 minutes to be in a semi-cured state. Thus, a structure formed by the glass plates the gas barrier supports 16, and the resin layer 14 as shown in FIG. 5C was prepared. The resin layer 14 was adjusted to have a width of 3 mm and a thickness of 50 μm.

As shown in FIG. 5C, the polymerizable composition for forming the optical functional layer 12 was injected into the inside of the resin layer 14 using a dispenser under a nitrogen purged environment not to overflow from the resin layer and then the solvent was removed by heating at 80° C. for 10 minutes.

Thereafter, the other gas barrier support 16 was carefully attached not entrain air bubbles and cured by being irradiated with ultraviolet light from one surface at an irradiation dose of 1000 mJ/cm² using an air cooling metal halide lamp (manufactured by EYE GRAPHICS CO., LTD.) of 200 W/cm and further thermally cured by heating at 80° C. for 10 minutes. Further, the laminate was thermally cured by heating at 80° C. for 10 minutes to prepare a functional film.

The width of the resin layer 14 of the obtained functional film was 3 mm, and the thickness of each of the optical functional layer 12 and the resin layer 14 was 50 μm.

### Example 11

A laminate was prepared in the same manner as in Example 10 except that the polymerizable composition for forming the optical functional layer 12 was injected into the inside of the resin layer 14 using a dispenser under a nitrogen purged environment not to overflow from the resin layer and then aging was performed for 2 minutes at room temperature while maintaining the nitrogen purged state.

### Example 12

A functional film was prepared by the above-described injection method.

As the gas barrier supports 16, two sheets of B270 glass with an optically polished surface having a thickness of 500 μm and a size of 5 cm square, manufactured by Schott AG, were prepared.

The polymerizable composition for forming the resin layer was applied to the entire end portion of one gas barrier support 16 using a dispenser and baked at 80° C. for 15 minutes to be in a semi-cured state. The other gas barrier support 16 was carefully attached and thermally cured at 80° C. for 10 minutes. Thus, a structure having a cell-shaped partition as shown in FIG. 6B was obtained. The resin layer 14 was adjusted to have a width of 3 mm and a thickness of 50 μm, and an opening having a width of 2 mm was provided at the end of one side of the four side of the structure.

The above-described polymerizable composition for forming the optical functional layer was injected into the inside of the structure using a vacuum method, cured by being irradiated with ultraviolet light from one surface at an irradiation dose of 1000 mJ/cm² using an air cooling metal halide lamp (manufactured by EYE GRAPHICS CO., LTD.) of 200 W/cm, and further thermally cured by heating at 80° C. for 10 minutes.

The width of the resin layer of the obtained laminate was 3 min, the thickness of each of the optical functional layer and the resin layer was 50 μm, and the opening portion was filled with the optical functional layer.

Next, in the laminated product 50 in which a plurality of functional films 10 were superimposed using a general sputtering apparatus by superimposing 100 sheets of the obtained laminates, a first inorganic layer was formed only on the side surface with the opening portion. Titanium was used as a target and argon was used as a discharge gas. The film formation pressure was 0.5 Pa, the film formation output was 400 W, and the arrival film thickness was 10 nm.

Subsequently, a copper layer having a film thickness of 75 nm was formed on the first inorganic layer as a second inorganic layer in the same manner as in the formation of the first layer except that the target was changed from titanium to copper.

Further, a third inorganic layer was formed on the second inorganic layer in the following manner.

First, the laminated product in which the second inorganic layer was formed was washed with pure water, immersed in a bath filled with a commercially available surfactant for 20 seconds, and degreased. Next, after being washed with water, the laminated product was immersed in a 5% aqueous sulfuric acid solution for 5 seconds, subjected to an acid activation treatment, and washed with water again.

The washed laminated product was hooked and fixed to a jig and conduction was confirmed by a tester. Thereafter, the laminated product was immersed in a 5% aqueous nitric acid solution for 10 seconds, subjected to an acid activation treatment and then subjected to an electroplating treatment in a copper sulfate bath under the conditions of a current density of 3.0 A/dm² for 5 minutes. Thus, a third inorganic layer as a metal plating layer was formed on the second layer. Thereafter, through washing with water and a rust prevention treatment, excessive moisture was removed with air and thus a functional film in which three metal layers were formed on the end surface of the resin layer 14 with the opening was obtained.

Next, the laminated product in which three metal layers were formed on the end surface was sheared by an external force in a horizontal direction to the surface of the functional film 10 and separated into each functional film 10. Thus, the functional layer laminate in which three metal layers were formed on the end surface of the resin layer 14 with the opening was obtained. The thickness of the metal layer was 5 μm according to observation with an optical microscope.

The opening of the resin layer 14 was sealed with the metal layers.

### Example 13

A functional film was prepared in the same manner as in Example 12 except that the polymerizable composition for forming the functional layer in Example 12 was injected and then aging was performed under nitrogen purge at room temperature for 2 minutes.

### Example 14

A laminate was prepared in the same manner as in Example 10 except that a structure formed by the glass plate of the gas barrier support 16 and the resin layer 14 shown in FIG. 5C was prepared by applying the above-described polymerizable composition for forming the resin layer 14 to the entire end surface of one gas barrier support 16 using a dispenser, then baking the composition at 80° C. for 30 minutes to be in a completely cured state, and after the polymerizable composition for forming the optical functional layer 12 was injected, the polymerizable composition which became the resin layer 14 was applied to the resin layer 14 as final coating such that the thickness after drying was 1 μm, and then one gas barrier support 16 was attached to the structure.

[Width Measurement of Binder Infiltrated Layer]

The width of the binder infiltrated layer 14a of the prepared functional film was measured in the following manner.

The interface between the optical functional layer 12 and the resin layer 14 was exposed by cutting the functional film.

The cross section was horizontally scanned with TOF-SIMS across the functional film from the optical functional layer 12 to the resin layer 14 and a region in which a component derived from acrylate of the optical functional layer 12 as a fragment ion was detected (binder infiltrated layer) was mapped and the position of the interface (optical interface) between the optical functional layer 12 and the resin layer 14 that could be observed with an optical microscope were compared to quantitatively determine whether or not the binder infiltrated layer was formed from the optical interface to the inside of the resin layer 14.

The spatial resolution in this measurement method was 0.01 μm, and a case where the width did not satisfy the value was expressed as “less than 0.01 μm (<0.01)”. In addition, a case where the width of the infiltrated layer was more than 15 μm was expressed as “15 μm or more (>15)” to avoid complicatedness of the test.

[Evaluation]

The following evaluations were performed on the prepared functional films.

<Initial Center Brightness>

The initial center brightness (Y) of the prepared functional film was measured by the following procedure.

First, the prepared functional film was cut into a size of 1-inch square. On the other hand, a commercially available tablet terminal (Kindle (registered trademark) Fire HDX 7″, manufactured by Amazon.com, Inc.) was disassembled to extract a backlight unit.

The functional film was placed on a light guide plate of the extracted backlight unit and two prism sheets whose surface directions were orthogonal to each other were superimposed thereon. The brightness of light which was emitted from a blue light source and passed through the functional film and the two prism sheets was measured using a brightness meter (SR3, manufactured by Topcon Corporation) provided at a distance of 740 mm perpendicular to the surface of the light guide plate, and this measured value was used as the initial center brightness (Y).

The evaluation standards of the initial center brightness (Y) are as follows. In a ease where the evaluation result is A or B, it can be determined that the emission efficiency is satisfactorily maintained.

A: 12000 cd/m²<Y

B: 10000 cd/m²<Y≤12000 cd/m²

C: 8000 cd/m²<Y≤10000 cd/m²

D: 8000 cd/m²≤Y

<High Temperature Durability>

After the initial center brightness was measured, in a room held at 85° C. the functional film was placed on a commercially available blue light source (OPSM-H150X142B, manufactured by OPTEX-FA Co., Ltd.), and the functional film was continuously irradiated with blue light for 1000 hours.

After the continuous irradiation, the functional film was extracted and the following evaluation was performed.

<<Center Brightness>>

The center brightness (Y′) after a high temperature durability test was measured by the same procedure as described above.

A rate of change (α) in the center brightness (Y′) after the high temperature durability test with respect to the initial center brightness (Y) measured in advance was calculated by the following equation and evaluated as an index of change in brightness based on the following standards.

α=Y′/Y

In a case where the evaluation result is A or B, it can be determined that the emission efficiency is satisfactorily maintained.

A: 0.95 <α

B: 0.7<α≤0.95

C: 0.5<α≤0.7

D: 0.5≥α

<<Display Unevenness>>

The functional film was mounted on a commercially available tablet terminal (Kindle (registered trademark) Fire HDX 7″, manufactured by Amazon.com, Inc.) and the brightness of the edge portion of the functional film was measured with a brightness meter (ProMetric, manufactured by Radiant Zemax, LLC.).

A ratio (β) between the initial center brightness (Y) measured in advance and the brightness Y″ at a position 1 mm from the end portion after the high temperature durability test was calculated by the following equation and evaluated based on the following standards.

β=Y″/Y

In a case where the evaluation result is A or B, it can be determined that there is no problem in display unevenness.

A: 0.95<β

B: 0.7<β≤0.95

C: 0.5<β≤0.7

D: 0.5≥β

<Adhesiveness>

With respect to the prepared functional film, the adhesiveness between the optical functional layer 12 and the resin layer 14 was evaluated in the following manner.

<<Bending Test>>

With respect to the functional films of Examples 1 to 9 and Comparative Examples 1 to 3, the adhesiveness between the optical functional layer 12 and the resin layer 14 was evaluated in the following manner.

An operation of bending the prepared functional film along a mandrel having a diameter φ of 8 mm was repeatedly performed 100 times at the same portion. After the test, whether or not a void caused by peeling-off near the interface between optical functional layer 12 and the resin layer 14 was formed in the bent region was observed using a differential interference microscope and evaluated based on the following standards. In a case where the evaluation result is A or B, it can be determined that there is no problem in interlaminar adhesion.

A: There is no change at the entire interface between the optical functional layer 12 and the resin layer 14 (no peeling-off occurs).

B: A void of less than 0.1 mm is formed in a part of the interface between the optical functional layer 12 and the resin layer 14.

C: A void of 0.1 mm or more and less than 1 mm is formed in a part of the interface between the optical functional layer 12 and the resin layer 14.

D: A void of 1 mm or more is formed in a part of the interface between the optical functional layer 12 and the resin layer 14.

<<Heat Cycle Test>>

With respect to the functional films of Examples 10 to 14, that is, the functional films prepared by a dam filling method and the injection method, the adhesiveness between the optical functional layer 12 and the resin layer 14 was evaluated in the following manner.

A process of immersing the prepared functional film in hot water at 100° C. for 30 minutes and then immersing the functional film in ice water at 0° C. for 30 minutes was repeatedly performed 100 times. After the test, whether or not a void caused by peeling-off near the interface between optical functional layer 12 and the resin layer 14 was formed in the bent region was observed using a differential interference microscope and evaluated based on the following standards.

In a case where the evaluation result is A or B, it can be determined that there is no problem in interlaminar adhesion.

A: There is no change at the entire interface between the optical functional layer 12 and the resin layer 14 (no peeling-off occurs).

B: A void of less than 0.1 mm is formed in a part of the interface between the optical functional layer 12 and the resin layer 14.

C: A void of 0.1 mm or more and less than 1 mm is formed in a part of the interface between the optical functional layer 12 and the resin layer 14.

D: A void of 1 mm or more is formed in a part of the interface between the optical functional layer 12 and the resin layer 14.

The results are shown in the following table.

TABLE 1

| | | | | Thickness | | Width of | | High temperature | | | |
|---|---|---|---|---|---|---|---|---|---|---|---|
| | Resin layer | | | of optical | | binder | Initial | durability | | | |
| | | Thick- | Oxygen | functional | Difference | infiltrated | center | Center | Display | Adhesiveness | |
| | Width | ness | permeability | layer | in thickness | layer | brightness | brightness | unevenness | | Heat |
| | [mm] | [μm] | [cc/(m² · day · atm)] | [μm] | [%] | [μm] | (Y) | (α) | (β) | Bending | cycle |
| Example 1 | 3 | 50 | 0.4 | 50 | 0 | 0.05 | A | A | A | A | — |
| Example 2 | 1 | 50 | 1.2 | 50 | 0 | 0.05 | A | B | A | A | — |
| Example 3 | 0.5 | 50 | 2.4 | 50 | 0 | 0.05 | A | B | A | A | — |
| Example 4 | 3 | 40 | 0.4 | 50 | 20 | 0.05 | A | A | B | B | — |
| Example 5 | 3 | 50 | 0.4 | 50 | 0 | 0.5 | A | A | A | A | — |
| Example 6 | 3 | 50 | 0.4 | 50 | 0 | 2 | A | A | A | A | — |
| Example 7 | 3 | 50 | 0.4 | 50 | 0 | 8 | A | B | A | A | — |
| Comparative | — | — | — | 50 | — | — | A | D | D | — | — |
| Example 1 | | | | | | | | | | | |
| Comparative | 3 | 30 | 0.4 | 50 | 40 | 0.05 | A | A | D | D | — |
| Example 2 | | | | | | | | | | | |
| Comparative | 0.1 | 50 | 12 | 50 | 0 | 0.05 | A | C | D | A | — |
| Example 3 | | | | | | | | | | | |
| Example 8 | 3 | 50 | 0.4 | 50 | 0 | 12 | A | B | B | A | — |
| Example 9 | 3 | 50 | 0.4 | 51 | 0 | <0.01 | A | A | A | C | — |
| Example 10 | 3 | 50 | 0.4 | 50 | 0 | 0.01 | A | A | A | — | B |
| Example 11 | 3 | 50 | 0.4 | 50 | 0 | 1 | A | A | A | — | A |
| Example 12 | 3 | 50 | 0.4 | 50 | 0 | 0.02 | A | A | A | — | A |
| Example 13 | 3 | 50 | 0.4 | 50 | 0 | 1 | A | A | A | — | A |
| Example 14 | 3 | 50 | 0.4 | 50 | 0 | <0.01 | A | A | A | — | C |

Examples 1 to 9 and Comparative Examples 1 to 3 were prepared by printing.
Examples 10, 11 and 14 were prepared by the dam filling method.
Examples 12 and 13 were prepared by the injection method.
A difference in thickness (%) is |(thickness of optical functional layer) − (thickness of resin layer)| ÷ (thickness of optical functional layer) × 100.

As shown in Table 1, according to the functional film of the present invention, it is possible to obtain a functional film capable of preventing the deterioration of the quantum dots even in a high temperature environment, not causing peeling-off between the optical functional layer 12 and the resin layer even by bending or thermal impact, and having excellent durability.

In particular, it is possible to obtain a functional film having excellent high temperature durability and not easily causing internal peeling-off even by bending or thermal impact by appropriately providing the binder infiltrated layer between the resin layer 14 and the optical functional layer. In Examples 9 and 14 having almost no binder infiltrated layer, compared to other examples, the adhesiveness is deteriorated but the high temperature durability is extremely excellent. Thus, as tong as high adhesiveness is not required, the functional films can be suitably used for various applications by utilizing excellent high temperature durability.

From the above results, the effects of the present invention are apparent.

The functional film can be suitably used for various optical applications such as an LCD.

### EXPLANATION OF REFERENCES

10, 20: functional film

12: optical functional layer

14: resin layer

14a: binder in filtrated layer

16: gas barrier support

24: end surface inorganic layer (inorganic layer)

26, 26A: first end surface inorganic layer

28, 28A: second end surface inorganic layer

30: sealing

What is claimed is:

1. A functional film comprising:
an optical functional layer;
a resin layer that surrounds end surfaces of the optical functional layer; and
gas barrier supports between which the optical functional layer and the resin layer are sandwiched,
wherein an oxygen permeability of the resin layer is 10 cc/(m²·day·atm) or less, and a difference between a thickness of the optical functional layer and a thickness of the resin layer is within 30%.

2. The functional film according to claim 1,
wherein an oxygen permeability of the gas barrier support is 0.1 cc/(m²·day·atm) or less.

3. The functional film according to claim 1,
wherein the optical functional layer includes a cured product of a polymerizable compound as a binder, and a hinder infiltrated layer formed by infiltration of the binder into the resin layer has a width of 0.01 to 10 μm in a plane direction of the optical functional layer.

4. The functional film according to claim 1, further comprising:
an inorganic layer that covers at least a part of an outer end surface of the resin layer.

5. The functional film according to claim 4,
wherein the inorganic layer is formed of metal.

6. The functional film according to claim 4,
wherein a plurality of the inorganic layers are provided.
